(19) United States
(12) Patent Application Publication
(10) Pub. No.: US 2020/0235317 A1
(43) Pub. Date: Jul. 23, 2020

(54) ORGANIC LIGHT EMITTING DIODES AND COMPOSITIONS THEREFOR COMPRISING PHTHALOCYANINE DERIVATIVES

(71) Applicant: THE GOVERNING COUNCIL OF THE UNIVERSITY OF TORONTO, Toronto (CA)

(72) Inventors: Timothy P. BENDER, Toronto (CA); Trevor PLINT, Toronto (CA); Benoit LESSARD, Toronto (CA)

(21) Appl. No.: 16/650,240

(22) PCT Filed: Sep. 25, 2018
(86) PCT No.: PCT/CA2018/051207

§ 371 Date: Mar. 24, 2020

Related U.S. Application Data
(60) Provisional application No. 62/562,747, filed on Sep. 25, 2017.

(51) Int. Cl. H01L 51/00; C09K 11/06; C09K 11/02; C07F 5/02

(52) U.S. Cl. CPC H01L 51/0078; C09K 11/06; C09K 11/02; H01L 51/0081; H01L 51/5072; C07F 5/022; C09K 2211/1022; H01L 2251/558; H01L 51/006

(57) ABSTRACT

The disclosure relates to a light emitting composition comprising a light emitting agent that includes at least one boron subphthalocyanine (BsubPc) derivative and at least one boron subphthalocyanine with an extended π-conjugation (BsubNc) derivative. The luminance spectrum of the light emitting agent may reveal peaks at particular wavelengths or “color targets” from parts of the “visible” portion of the electromagnetic spectrum. The light emitting composition may be part of an organic light emitting diode (OLED).

### CROSS-REFERENCE TO RELATED APPLICATIONS

This application claims priority from U.S. Provisional Patent Application No. 62/562,747 filed Sep. 25, 2017, the contents of which are hereby incorporated by reference.

### FIELD

The present disclosure relates to light emitting materials. More particularly, the present disclosure relates to organic light emitting materials.

### BACKGROUND

Lighting sources such as compact fluorescent bulbs, fluorescent tube lights and conventional light emitting diodes (LEDs), though perceived as white, suffer from relatively cool color temperatures. In addition to subjective perception, there is a growing body of literature that suggests that the quality of light matters as much as the quantity. Studies have examined the correlation between the quality of indoor light and workplace productivity, employee satisfaction and number of sick days taken. These studies suggest that cool color temperature lighting may be less suitable for indoor lighting as compared to warm color temperature lighting, such as with incandescent lighting.

Organic light emitting diodes (OLEDs), once an academic curiosity, are gaining acceptance as a light-emitting technology as consumer display electronics have been adopting them. The luminance spectrum of light emitters may reveal peaks at particular wavelengths. Peaks at certain wavelengths or “color targets” may be desirable for various reasons. Many of these color targets are of growing commercial relevance and market interest. For example, it may be desirable to produce indoor lighting having desirable properties. Also, since many objects, including human skin, are rich in red pigments, red emitting compounds may be of interest. Further, broad spectrum emitters may be of interest since they may reveal different colored objects closer to an ideal blackbody light source.

Unlike LEDs, whose emission spectra are confined to a limited set of emitting materials, the color of modern OLEDs may be tuned to achieve better control of the emission spectra. The altering of chemical structures of light emitting organic molecules may allow for tuning of the electrical band gap, resulting in the ability to tailor the peak emission wavelength. Also, due to multi-peak spectral characteristics of some OLEDs, it may be important to measure how well they might illuminate real-world environments.

In US20160351834, which is herein incorporated by reference in its entirety, a phenoxy-BsubPc, F₅BsubPc, was developed and incorporated into various OLED devices. F₅BsubPc has a unique and pure orange electroluminescent emission ˜580 nm with an unusually narrow full width at half maximum (FWHM) of 40 nm. In addition, the electroluminescence emission of BsubPc showed a secondary peak at ˜720 nm when in an aggregated, which could be produced by varying the dopant architecture. In M. G. Helander et al, ACS Applied Materials & Interfaces, 2010, 2, 3147-3152, which is herein incorporated by reference in its entirety, secondary emissions associated with BsubPc aggregates were tuned out by reducing the degree of intermolecular aggregation in BsubPc containing OLEDs.

Some molecules used in OLEDs exhibit emission spectra with more than one peak (see, for example, K. T. Kamtekar, A. P. Monkman and M. R. Bryce, Advanced Materials, 2010, 22, 572-582 and G. M. Farinola and R. Ragni, Chemical Society Reviews, 2011, 40, 3467-3482, which are herein incorporated by reference in their entireties). These molecules are commonly used as dopants within a host layer as opposed to neat layers. The most common dual-emitting compounds have been either co-polymers of two distinct emitter moieties (see, for example, D. A. Poulsen, B. J. Kim, B. Ma, C. S. Zonte and J. M. J. Fréchet, Advanced Materials, 2010, 22, 77-82 and K. L. Paik, N. S. Baek, H. K. Kim, J.-H. Lee and Y. Lee, Macromolecules, 2002, 35, 6782-6791, which are herein incorporated by reference in their entireties) or chelates of rare earth metals (see, for example, Y. Liu, M. Pan, Q.-Y. Yang, L. Fu, K. Li, S.-C. Wei and C.-Y. Su, Chemistry of Materials, 2012, 24, 1954-1960 and Y.-A. Li, S.-K. Ren, Q.-K. Liu, J.-P. Ma, X. Chen, H. Zhu and Y.-B. Dong, Inorganic Chemistry, 2012, 51, 9629-9635, which are herein incorporated by reference in their entireties). Metal-free small molecule dual emitters such as derivatives of BsubPc are therefore rare, making them of particular interest.

There is a need for improved light emitting materials and OLED architectures.

### SUMMARY

In an aspect, there is provided a light emitting composition comprising a light emitting agent comprising at least one boron subphthalocyanine (BsubPc) derivative as set out by formula:

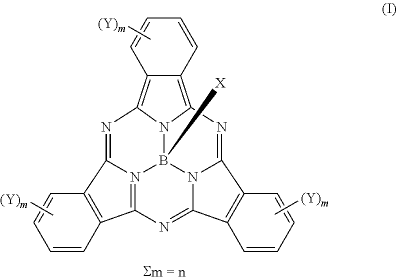

wherein X is a halogen, an alkoxy or a phenoxy,
wherein Y of each lobe is, independently, a hydrogen, a halogen, an alkoxy or a phenoxy,
wherein m is an integer chosen from 0, 1, 2, 3, or 4
wherein n is an integer that is 0, 3, 6, 9, or 12;
and at least one boron subphthalocyanine with an extended π-conjugation (BsubNc) derivative as set out by formula:

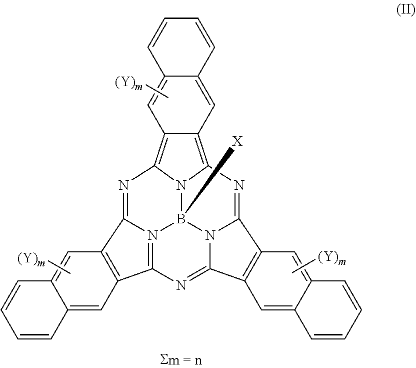

wherein X is a halogen, an alkoxy or a phenoxy,
wherein Y each lobe is, independently, a hydrogen, a halogen, an alkoxy or a phenoxy,
wherein m is an integer chosen from 0, 1 or 2,
wherein n is an integer chosen from 3 or 6; or
any combination thereof.

In some embodiments, the X is fluorine, chlorine, bromine or iodine. In some embodiments, the X is fluorine or chlorine. In some embodiments, the X is an alkoxy or a phenoxy, limited to four carbons. In some embodiments, the Y is fluorine, chlorine, bromine or iodine. In some embodiments, the Y is fluorine or chlorine. In some embodiments, the Y is an alkoxy or a phenoxy, limited to four carbons.

In some embodiments, the at least one BsubPc derivative comprises Cl-BsubPc, Cl-ClₙBsubNc, Cl—Cl₆-BsubPc or any combination thereof. In some embodiments, the at least one BsubPc derivative comprises Cl-BsubPc and Cl-ClₙBsubNc.

In some embodiments, the Cl-ClₙBsubNc is configured to absorb at least a portion of the photons emitted by the Cl-BsubPc.

In some embodiments, the at least one boron subphthalocyanine derivative exhibits a primary electroluminescent peak and wherein the at least one boron subphthalocyanine derivative is configured to exhibit a secondary electroluminescent peak.

In some embodiments, the light emitting material further includes a host material. In some embodiments, the host material comprises Alq₃ or NPB. In some embodiments, the host material comprises Alq₃.

In some embodiments, the light emitting composition consists of the at least one boron subphthalocyanine derivative.

In an aspect, there is provided an organic light emitting diode (OLED) comprising an emissive material comprising at least one boron subphthalocyanine (BsubPc) derivative as set out by formula:

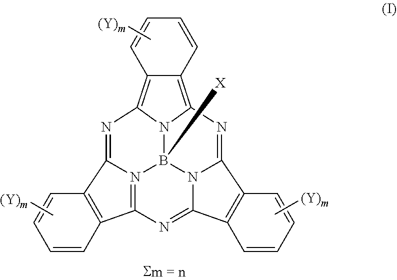

wherein X is a halogen, an alkoxy or a phenoxy,
wherein Y each lobe is, independently, a hydrogen, a halogen, an alkoxy or a phenoxy,
wherein m is an integer that is 0, 1, 2, 3, or 4,
wherein n is an integer that is 0, 3, 6, 9, or 12;
and at least one boron subphthalocyanine with an extended π-conjugation (BsubNc) derivative as set out by formula:

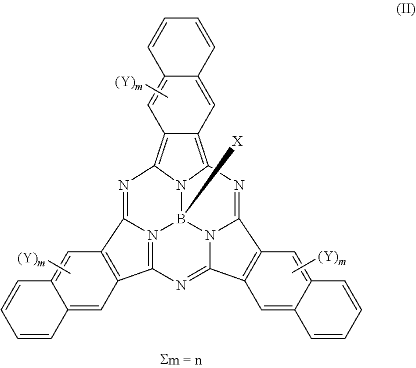

wherein X is a halogen, an alkoxy or a phenoxy,
wherein Y each lobe is, independently, a hydrogen, a halogen, an alkoxy or a phenoxy,
wherein m is an integer that is 0, 1 or 2,
wherein n is an integer that is 3 or 6; or
any combination thereof.

In some embodiments, the OLED includes an electron transport layer (ETL); and a hole transport layer (HTL). In some embodiments, the ETL comprises Alq₃. In some embodiments, the HTL comprises NPB or TCTA. In some embodiments, the ETL has a thickness of between about 30 nm and about 60 nm. In some embodiments, the HTL has a thickness of between about 35 nm and about 50 nm.

In some embodiments, the OLED further includes an interlayer, where the interlayer comprises the emissive material. In some embodiments, the interlayer has a thickness of between about 1 nm and about 60 nm. In some embodiments, the interlayer has a thickness of between about 5 nm and about 20 nm.

In some embodiments, the hole transport layer comprises the emissive material.

In some embodiments, the OLED produces light having a CRI of at least 60. In some embodiments, the OLED produces light having a R9 value of at least about 0. In some embodiments, the OLED produces light close having a CIE 1931 coordinate similar to that of a 60 W incandescent bulb of (0.44, 0.40).

In an aspect, there is provided a light emitting composition comprising a light emitting agent comprising at least one boron subphthalocyanine derivative as set out by formula:

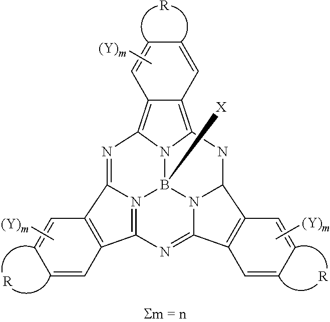

wherein R is present or absent and wherein, when present, R is a fused benzene ring;
wherein X is a halogen, an alkoxy or a phenoxy,
wherein Y of each lobe is, independently, a hydrogen, a halogen, an alkoxy or a phenoxy,
wherein m is an integer that is 0, 1 or 2,
wherein n is an integer that is 3 or 6; or
any combination thereof.

In an aspect, there is provided at least one boron subphthalocyanine derivative as set out by formula:

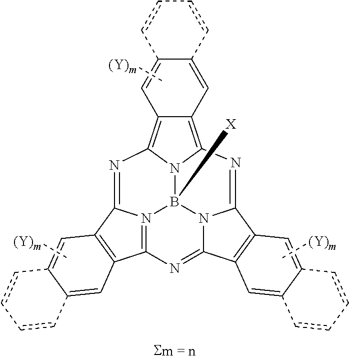

wherein X is a halogen, an alkoxy or a phenoxy,
wherein Y of each lobe is, independently, a hydrogen, a halogen, an alkoxy or a phenoxy,
wherein m is an integer that is 0, 1 or 2,
wherein n is an integer that is 3 or 6; or
any combination thereof.

### BRIEF DESCRIPTION OF DRAWINGS

In the drawings, embodiments of the invention are illustrated by way of example. It is to be expressly understood that the description and drawings are only for the purpose of illustration and as an aid to understanding, and are not intended as a definition of the limits of the invention.

FIG. 1 shows the optical normalized absorbance for Cl-BsubPc. The normalized solid-state photoluminescence emission under 520 nm, and 630 nm excitation are shown, and are typical of the BsubPc chromophore.

FIG. 2 shows the molecular structure of materials used to produce OLEDs according to embodiments of the invention and the generic architecture of OLEDs produced according to some embodiments of the invention.

FIG. 3 shows current Density (left axis, open squares) and Luminance (right axis, filled squares) for OLEDs with generic structure glass/ITO (120 nm)/X-BsubPc (50 nm)/Alq₃ (60 nm)/LiF (1 nm)/Al (60 nm), compared to control OLED having structure of glass/ITO (120 nm)/NPB (50 nm)/Alq3 (60 nm)/LiF (1 nm)/Al (60 nm) (black squares). X-BsubPc denotes chloro boron subphthalocyanine (Cl-BsubPc, pink squares), pentafluorophenoxy boron subphthalocyanine (F₅BsubPc, violet squares), and chloro hexachloro boron subphthalocyanine (Cl—Cl₆-BsubPc, cyan squares).

FIG. 4A shows spectral emission for X-BsubPc OLEDs produced in accordance with some embodiments of the invention, normalized relative to the Alq₃ emission peak. X-BsubPc denotes Cl-BsubPc, (pink lines), F₅BsubPc, (violet lines), Cl—Cl₆-BsubPc, (cyan lines). The control NPB/Alq₃ OLED spectral emission profile (black line) is included for comparison.

FIG. 4B shows spectral emission for X-BsubPc OLEDs produced in accordance with some embodiments of the invention, normalized relative to the primary BsubPc emission peak. X-BsubPc denotes Cl-BsubPc, (pink lines), F₅BsubPc, (violet lines), Cl—Cl₆-BsubPc, (cyan lines). The control NPB/Alq₃ OLED spectral emission profile (black line) is included for comparison.

FIG. 5 shows CIE (1931) (x, y) color co-ordinates for X-BsubPc OLEDs produced in accordance with some embodiments of the invention. X-BsubPc denotes Cl-BsubPc/Alq₃ (open square), F5BsubPc/Alq₃ (open diamond), and Cl-Cl6-BsubPc/Alq₃ (open pentagon). The control NPB/Alq₃ OLED (open circle) is presented for comparison.

FIG. 6 shows the Current Density (left axis, open squares) and Luminance (right axis, filled squares) for OLEDs produced in accordance with some embodiments of the invention. The OLEDs have generic structure glass/ITO (120 nm)/Cl-BsubPc (50 nm)/Alq₃ (X nm)/LiF (1 nm)/AI (60 nm), where X=60 nm (dark blue squares), X=50 nm (purple squares), X=40 nm (pink squares), X=30 nm (dark red squares). These OLED are compared to control OLED having structure of glass/ITO (120 nm)/NPB (50 nm)/Alq₃ (60 nm)/LiF (1 nm)/AI (60 nm) (black squares).

FIG. 7A shows spectral emission for Cl-BsubPc (50 nm)/Alq₃ (X nm) OLEDs produced in accordance with some embodiments of the invention, normalized relative to the Alq3 emission peak, where X=60 nm (dark blue lines), X=50 nm (purple lines), X=40 nm (pink lines), X=30 nm (dark red lines). These OLEDs are compared to control NPB (50 nm)/Alq₃ (60 nm) device (black line).

FIG. 7B shows spectral emission for Cl-BsubPc (50 nm)/Alq₃ (X nm) OLEDs produced in accordance with some embodiments of the invention, normalized relative to the main BsubPc emission peak, where X=60 nm (dark blue lines), X=50 nm (purple lines), X=40 nm (pink lines), X=30 nm (dark red lines). These OLEDs are compared to control NPB (50 nm)/Alq₃ (60 nm) device (black line).

FIG. 8 shows CIE (1931) (x, y) color co-ordinates for Cl-BsubPc (50 nm)/Alq₃ (X nm) OLEDs produced in accordance with some embodiments of the invention, where X=60 nm (open square), X=50 nm (top-half black square), X=40 nm (right-half black square), and X=30 nm (bottom-half black square). The control NPB/Alq3 OLED (open circle) is presented for comparison.

FIG. 9 shows Current Density (left axis, open squares) and Luminance (right axis, filled squares) for OLEDs produced in accordance with some embodiments of the invention. The OLEDs have generic structure glass/ITO (120 nm)/NPB (50 nm)/Cl-BsubPc (X nm)/Alq₃ (60 nm)/LiF (1 nm)/AI (60 nm), where X=5 nm (dark green squares), X=10 nm (light green squares), X=15 nm (orange squares), X=20 nm (red squares). These OLED are compared to control OLED having structure of glass/ITO (120 nm)/NPB (50 nm)/Alq₃ (60 nm)/LiF (1 nm)/AI (60 nm) (black squares).

FIG. 10A shows Spectral emission for NPB (50 nm)/Cl-BsubPc (X nm)/Alq₃ (60 nm) OLEDs produced in accordance with some embodiments of the invention normalized relative to the Alq₃ emission peak, where X=5 nm (dark green lines), X=10 nm (light green lines), X=15 nm (orange lines), X=20 nm (red lines). These OLEDs are compared to control NPB (50 nm)/Alq₃ (60 nm) device (black line).

FIG. 10B shows Spectral emission for NPB (50 nm)/Cl-BsubPc (X nm)/Alq₃ (60 nm) OLEDs produced in accordance with some embodiments of the invention, normalized relative to the main BsubPc emission peak, where X=5 nm (dark green lines), X=10 nm (light green lines), X=15 nm (orange lines), X=20 nm (red lines). These OLEDs are compared to control NPB (50 nm)/Alq₃ (60 nm) device (black line).

FIG. 11 shows CIE (1931) (x, y) color co-ordinates for NPB (50 nm)/Cl-BsubPc (X nm)/Alq₃ (60 nm) OLEDs produced in accordance with some embodiments of the invention, where X=5 nm (downward pointing triangle), X=10 nm (right pointing triangle), X=15 nm (left pointing square), and X=20 nm (upward pointing triangle). The control NPB/Alq₃ OLED (open circle) is presented for comparison.

FIG. 12 shows the molecular structures, solution state absorption profile (solid lines) and fluorescence (dashed lines) of chloro boron subphthalocyanine (Cl-BsubPc, purple and orange lines) and chloro boron subnaphthalocyanine (Cl-ClₙBsubNc, blue and red lines). Molecular structures are shown above their respective absorption and fluorescent emission plots. The molecular structures for aluminium triquinolate (Alq₃) and N,N′-Di(1-naphthyl)-N,N′-diphenyl-(1,1′-biphenyl)-4,4′-diamine (NPB) are shown at right.

FIG. 13A illustrates the highest occupied molecular orbital (HOMO) and lowest unoccupied molecular orbital (LUMO) energies for NPB, Alq₃, Cl-BsubPc and Cl-ClₙBsubNc. Values are drawn from Tao et al, (2000), Tanaka et al (2007), Kobayashi (1999) and Verreet et al (2009), respectively (these references are more fully identified in the detailed description.

FIG. 13B illustrates OLEDs architectures of OLEDs produced in accordance with some embodiments of the invention. In these embodiments, the devices had total hole transport layer (HTL) and total electron transport layer (ETL) thicknesses of 50 nm and 60 nm, respectively.

FIG. 14A shows the Current Density (left axis, open squares) and Luminance (right axis, filled squares) for OLEDs produced in accordance with some embodiments of the invention. The OLEDs have the generic structures glass/ITO (120 nm)/MoOₓ (1 nm)/NPB (35 nm)/NPB:X (5%) (15 nm)/Alq₃ (60 nm)/LiF (1 nm)/Al (100 nm), where X is either Cl-BsubPc (light green shapes), or Cl-ClₙBsubNc (dark green shapes); and glass/ITO (120 nm)/MoOₓ (1 nm)/NPB (50 nm)/Alq₃:X (5%) (15 nm)/Alq₃ (45 nm)/LiF (1 nm)/Al (100 nm), where X is either Cl-BsubPc (orange shapes), or Cl-ClₙBsubNc (red shapes). A control device having the structure glass/ITO (120 nm)/MoOₓ(1 nm)/NPB (50 nm)/Alq₃ (60 nm)/LiF (1 nm)/Al (100 nm) (black) is presented as a point of comparison.

FIG. 14B shows the Spectral Emission Profile of the OLEDs of FIG. 14A. The spectral outputs have been normalized relative to the Alq₃ emission peak of around 520 nm. In addition, the color of the devices with doped with 5% Cl-BsubPc in each of the HTL and the ETL are shown.

FIG. 15A shows Current Density (left axis, open squares), Luminance (right axis, filled squares), for OLEDs produced in accordance with some embodiments of the invention. The OLEDs have generic structures: glass/ITO (120 nm)/MoOₓ (1 nm)/X (50 nm)/Alq₃ (60 nm)/LiF (1 nm)/AI (100 nm), where X is either neat Cl-BsubPc (pink shapes), or neat Cl-ClₙBsubNc (red shapes); and glass/ITO (120 nm)/MoOₓ (1 nm)/NPB (50 nm)/Alq₃:X (5%) (15 nm)/Alq₃ (45 nm)/LiF (1 nm)/AI (100 nm), where X is either Cl-BsubPc (orange shapes), or Cl-ClₙBsubNc (red shapes).

FIG. 15B shows Spectral Emission Profile of the OLEDs of FIG. 15A. The spectral outputs have been normalized relative to the Alq₃ emission peak of around 520 nm.

FIG. 16A shows Current Density (left axis, open squares), Luminance (right axis, filled squares) for OLEDs produced in accordance with some embodiments of the invention. The OLEDs have generic structures: X/glass (1 mm)/ITO (120 nm)/NPB (50 nm)/Alq₃ (60 nm)/LiF (1 nm)/Al (100 nm), where X is either Cl-BsubPc (20 nm) (orange shapes), or bare glass (black shapes). Note that in the first device, the Cl-BsubPc layer is not in electrical contact with the active layers of the device.

FIG. 16B shows Spectral Emission Profile of the OLEDs of FIG. 16A. The spectral outputs have been normalized relative to the Alq₃ emission peak of around 520 nm.

FIG. 17A shows Current Density (left axis, open squares), Luminance (right axis, filled squares), for OLEDs produced in accordance with some embodiments of the invention. The OLEDs have generic structures: glass/ITO (120 nm)/NPB (50 nm)/Alq₃: (X %)(15 nm)/Alq₃ (45 nm)/LiF (1 nm)/Al (100 nm), where X is either 5% (orange shapes) or 20% (yellow shapes), respectively. A control device having the structure glass/ITO (120 nm)/MoOₓ(1 nm)/NPB (50 nm)/Alq₃ (60 nm)/LiF (1 nm)/Al (100 nm) (black shapes) is presented as a point of comparison n.

FIG. 17B shows Spectral Emission Profile of the OLEDs of FIG. 17A. The spectral outputs have been normalized relative to the Alq₃ emission peak of around 520 nm.

FIG. 18A shows Current Density (left axis, open squares), Luminance (right axis, filled squares) for OLEDs produced in accordance with some embodiments of the invention. The OLEDs have generic structures: glass/ITO (120 nm)/MoOₓ(1 nm)/NPB (50 nm)/Alq₃: Cl-BsubPc (X %)+Cl-ClₙBsubNc (5%) (15 nm)/Alq₃ (45 nm)/LiF (1 nm)/Al (100 nm), where X is either 5% (light blue shapes) or 20% (dark blue shapes), respectively. A control device having the structure glass/ITO (120 nm)/MoOₓ(1 nm)/NPB (50 nm)/Alq₃ (60 nm)/LiF (1 nm)/Al (100 nm) (black shapes) is presented as a point of comparison.

FIG. 18B shows Spectral Emission Profile of the OLEDs of FIG. 18A. The spectral outputs have been normalized relative to the Alq₃ emission peak of around 520 nm.

FIG. 19 shows a CIE1931 (x,y) plot for OLEDs produced in accordance with some embodiments of the invention. CIE co-ordinates for 60 W lightbulb and the CIE1931 standard for true white are drawn from D. Pascale (2003), which is more fully identified in the detailed description.

FIG. 20 shows properties of a control OLED device made with NPB and Alq₃.

FIG. 21 shows is a diagram showing the color of the light produced by devices produced in accordance with some embodiments of the invention.

FIG. 22 illustrates OLED architectures of OLEDs produced in accordance with some embodiments of the invention. I

FIG. 23 illustrates OLED architectures of OLEDs produced in accordance with some embodiments of the invention. I

FIG. 24 illustrates OLED architectures of OLEDs produced in accordance with some embodiments of the invention. I

FIG. 25 illustrates properties of a BsubPc derivative according to some embodiments of the invention in contrast to other emissive materials.

FIG. 26A shows Current Density (left axis, open squares), Luminance (right axis, filled squares), for OLEDs produced in accordance with some embodiments of the invention. The OLEDs have generic structures: glass/ITO (120 nm)/NPB (50 nm)/Alq₃:Cl-BsubXc (5%)(15 nm)/Alq₃ (45 nm)/LiF (1 nm)/Al (100 nm), where X is P (orange shapes), N (yellow shapes) or both P and N (light blue squares). A control device having the structure glass/ITO (120 nm)/MoOₓ(1 nm)/NPB (50 nm)/Alq₃ (60 nm)/LiF (1 nm)/Al (100 nm) (black shapes) is presented as a point of comparison.

FIG. 26B shows Spectral Emission Profile of the OLEDs of FIG. 26A. The spectral outputs have been normalized relative to the Alq₃ emission peak of around 520 nm.

FIG. 27 shows a cascade mechanism for emissions according to some embodiments of the invention.

FIG. 28 shows spectral emission profiles of various sources of light.

FIG. 29 shows the molecular structure of materials used to produce OLEDs according to embodiments of the invention.

### DETAILED DESCRIPTION

Various embodiments and aspects of the disclosure will be described with reference to details discussed below. The description and drawings are illustrative of the invention and are not to be construed as limiting the invention. Numerous specific details are described to provide a thorough understanding of various embodiments of the present invention. However, in certain instances, well-known or conventional details are not described in order to provide a concise discussion of embodiments of the present disclosure.

As used herein, the term “turn on voltage” refers to the voltage at which luminance for an OLED exceeds 1 cd/m².

As used herein, the term “color rendering index” (CRI) refers to a measure of the effect of an illuminant on the color appearance of objects by conscious or subconscious comparison with their color appearance under a reference illuminant (such as an ideal blackbody light source, which has a CRI value of 100).

As used herein, the term “R9 value” refers to a measure of how well a light source renders red pigments. The R9 value has a theoretical maximum value of 100 for a black body emitter. The R9 value may be used to quantify the “warmth” of a light source.

One standard for color definition is the CIE 1931 (x,y) system, which converts visible spectral profiles into an individual point in Cartesian coordinates. The CIE standard for “pure white” is (0.33, 0.33).

Unless otherwise specified, any specified range or group includes each and every member of a range or group individually, as well as each and every possible sub-range or sub-group encompassed therein, and likewise with respect to any sub-ranges or sub-groups therein. Unless otherwise specified, any specified range is considered an inclusive range where the endpoints of the range are included in the specified range.

In an aspect, there is provided a light emitting composition comprising a light emitting agent comprising a boron subphthalocyanine derivative. The boron subphthalocyanine derivative is as set out by formula:

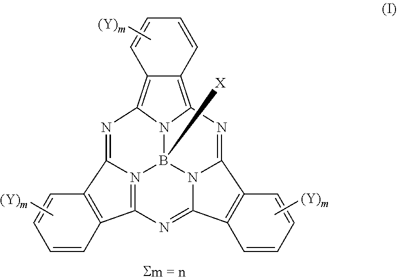

where X is a halogen, an alkoxy or a phenoxy,

where Y is a hydrogen, a halogen, an alkoxy or a phenoxy,

where m is an integer chosen from 0, 1, 2, 3, or 4

where n is an integer that is 0, 3, 6, 9, or 12;

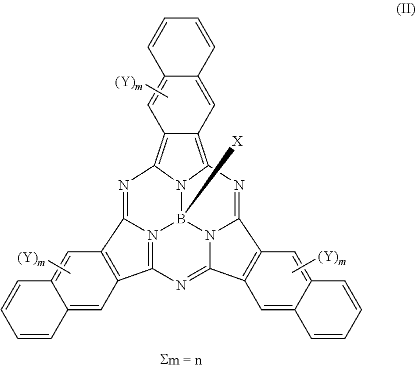

where X is a halogen, an alkoxy or a phenoxy,

where Y is a hydrogen, a halogen, an alkoxy or a phenoxy,

where m is an integer chosen from 0, 1 or 2,

where n is an integer chosen from 3 or 6; or

any combination thereof.

In some embodiments, X is fluorine, chlorine, bromine, or iodine. In some embodiments, X is fluorine or chlorine. In some embodiments, X is flourine. In some embodiments, X is an alkoxy or a phenoxy, limited to 4 carbons.

In some embodiments, Y is fluorine, chlorine, bromine, or iodine. In some embodiments, Y is fluorine or chlorine. In some embodiments, each of the moieties Y are the same halogen. In some embodiments, Y is an alkoxy or a phenoxy, limited to 4 carbons.

In some embodiments, the at least one boron subphthalocyanine derivative is selected from chloro boron subphthalocyanine (Cl-BsubPc), chloro boron subnaphthalocyanine (Cl-ClₙBsubNc), chloro hexachloro boron subphthalocyanine (Cl—Cl₆-BsubPc), or any combination thereof.

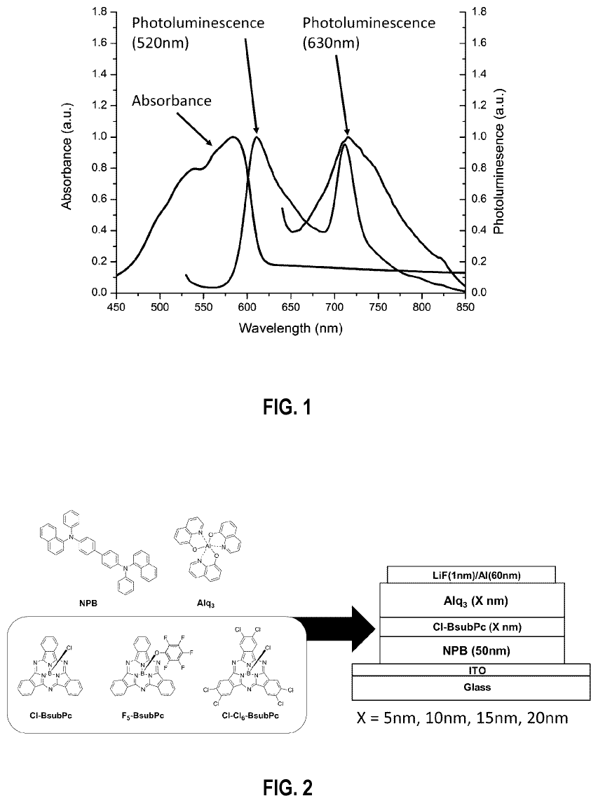

Boron subphthalocyanines (BsubPcs) are a synthetically versatile class of bowl-shaped organic semiconductor molecules whose electro-optical properties are of interest in the field of organic electronics. The molecular structure, optical absorbance, and fluorescence emission of select BsubPc chromophores are shown in FIGS. 1 and 12.

In some embodiments, the light emitting agent exhibits more than one peak in its emission spectra. In some embodiments, comprises a plurality of compounds. Each of the plurality of compounds may exhibit emission spectra having peaks at different frequencies. In some embodiments, the light emitting agent exhibits an aggregate effect. Combinations of such compounds or aggregate effects may result in a total emission spectrum having a broader range to more accurately reproduce the emission spectra of a blackbody. This may allow for the production of OLEDs with better white-emitting properties, for example, for white-emitting organic light emitting diodes (WOLEDs).

In some embodiments, the light emitting agent comprises Cl-BsubPc and Cl-ClₙBsubNc. In some embodiments, the Cl-ClₙBsubNc is configured to absorb at least a portion of the photons emitted by the Cl-BsubPc. In some embodiments, the ratio of the mass of the Cl-BsubPc and the mass of the Cl-ClₙBsubNc in the light emitting agent is between about 1:1 and about 4:1.

Cl-BsubNc is a structural variant of Cl-BsubPc with an extended π-conjugation, resulting in a red-shifted absorption and emission. Cl-BsubNc has been used as light harvesting material in optical photovoltaics. Additionally, Cl-BsubNc has been used in red-sensitive organic photoconductive films. However chemical processes for synthesizing Cl-BsubNc do not necessarily yield a pure compound. Rather, an alloyed mixture of bay-position chlorinated materials is typically produced. The basic photophysics and electronic properties of the alloyed mixture of Cl-BsubNc, including absorption and luminescent emission spectrum, electrochemistry, UPS and XPS are disclosed in J. D. Dang, D. S. Josey, A. J. Lough, Y. Li, A. Sifate, Z.-H. Lu, T. P. Bender, J. Mater. Chem. A, (2016), which is hereby incorporated by reference in its entirety. Since commercially available Cl-BsubNc is known to have been synthesized using such techniques, and based Dang et al, it will hereafter be referred to as Cl-ClₙBsubNc(s) to indicate its mixed alloyed composition.

In some embodiments, the at least one light emitting agent is present in the composition at a concentration of at least about 1, 2, 3, 4, 5, 10, 15, 20, 25, 30, 40, or 50% by mass. In some embodiments, the at least one light emitting agent is present in the composition at a concentration of up to about 50, 60, 70, 80, 90, 95, 96, 97, 98, 99, or even 100%.

In some embodiments, the light emitting composition comprises a host material. In some embodiments, the host material is NPB or Alq₃ In some embodiments, the host material is Alq₃.

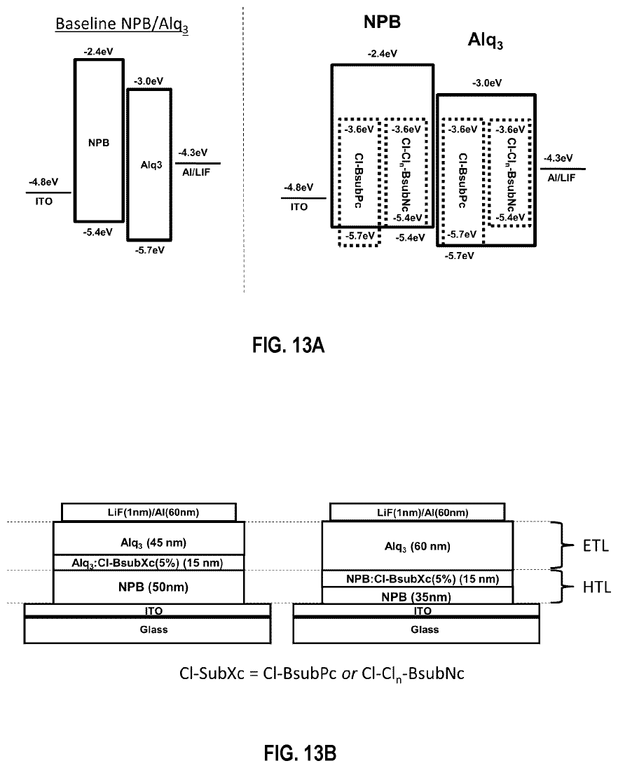

In some embodiments, the host material is selected based on the highest occupied molecular orbital (HOMO) and lowest unoccupied molecular orbital (LUMO). With reference to FIG. 13A, the energies of the highest occupied molecular orbital (HOMO) and lowest unoccupied molecular orbital (LUMO) for Cl-BsubPc, Cl-ClₙBsubNc, NPB and Alq₃ are shown.

In some embodiments, the at host material in the composition at a concentration of at least about 1, 2, 3, 4, 5, 10, 15, 20, 25, 30, 40, or 50% by mass. In some embodiments, the host material is present in the composition at a concentration of up to about 50, 60, 70, 80, 90, 95, 96, 97, 98, or 99% by mass.

In another aspect, there is provided an organic light emitting diode (OLED) comprising an emissive material that includes or is the light emitting composition as described above.

In some embodiments, the at least one boron subphthalocyanine derivative selected from Cl-BsubPc, Cl-ClₙBsubNc, Cl—Cl₆-BsubPc or any combination thereof.

In some embodiments, the OLED includes an electron transport layer (ETL) and a hole transport layer (HTL). In some embodiments the ETL, the HTL or both, comprise the emissive material. In some embodiments, the emissive material is disposed in a sublayer of the ETL, the HTL, or both.

In some embodiments, the ETL comprises Alq₃, the emissive material, or any combination thereof. Alq₃ has an emission spectra that includes a peak in a green wavelength range. The combination of the emissive material and the Alq₃ material provides emissions having multiple peaks in the visible range.

In some embodiments, the ETL has a thickness of between about 30 nm and about 60 nm.

In some embodiments, the ETL includes a green emitter or a blue emitter. In some embodiments where the ETL includes a green emitter or a blue emitter, reducing the thickness of the ETL tends to result in an OLED with a warmer color emission. In some embodiments, the emissive material causes a blue shift in the light from the green emitter or the blue emitter.

In some embodiments, the HTL comprises NPB, the emissive material, or any combination thereof.

In some embodiments, the HTL has a thickness of between about 35 nm and about 50 nm.

In some embodiments, the OLED comprises an interlayer disposed between the HTL and the ETL. In some embodiments, the interlayer comprises the emissive material.

In some embodiments, the interlayer has a thickness of between about 5 nm and about 20 nm.

In some embodiments, the OLED produces light having a CRI of at least about 40, 50, 60, or 70.

In some embodiments, the OLED produces light having a R9 value of at least about 0, 50, or 75. While commercial standards for acceptable R9 values are not well established, a recent report on high efficiency indoor light compiled by Pacific Northwest National Laboratory for the US Department of Energy states that white light sources with R9 values above 0 are “good,” those above 50 are “very good,” and those above 75 are “excellent”.

In some embodiments, the OLED emits an overall warm, white incandescent-like emission. In some embodiments, the OLED emits light close to the CIE 1931 standard for a 60 W incandescent bulb of (0.44, 0.40).

In an aspect, there is provided a method of producing an OLED comprising including providing a substrate, applying an anode to the substrate, applying a hole transport layer, optionally applying an interlayer, applying an electron transport layer, and applying a cathode. The hole transport layer, the electron transport layer, or the interlayer comprises a light emitting composition as described above.

In some embodiments, the OLED is “after-patterned” using Parylene-C deposition.

In some embodiments, the substrate is a Kapton/Lexan film coated with PEDOT:PSS.

### EXAMPLES

### Example 1—OLED Fabrication

OLED devices were fabricated on 25 mm by 25 mm glass substrates patterned with indium tin oxide (ITO) with a sheet resistance of 15 Ω/sq. ITO stripes 1 mm wide, 20 mm long and 120 nm thick formed the bottom contact of each OLED. The ITO patterned glass substrates were cleaned by hand with a mixture of detergent (Alconox) and de-ionized water, followed by sequential five-minute sonication in solutions of detergent and deionized water, clean deionized water, acetone, and methanol. The patterned glass substrates were stored under methanol for up to two weeks before use.

Prior to OLED fabrication, the cleaned ITO patterned glass substrates were treated with atmospheric plasma for five minutes and then transferred to a nitrogen atmosphere glove box (O₂<1 ppm, H₂O<25 ppm) integrated via load lock to a high vacuum vapor deposition chamber with a base pressure of ˜5-8×10⁻⁸ Torr and a working pressure of ˜1×10⁻⁷ Torr.

A series of layers were deposited on the treated ITO patterned substrate in the high vacuum vapor deposition chamber through a square shadow mask. Deposition rates were monitored by quartz crystal microbalance (QCM, Inficon) calibrated against neat films deposited on glass. Thickness of the device layers was measured by step edge contact profilometry (KLA Tencor P-16+).

The ITO layer was first coated with 1 nm of molybdenum oxide (MoOₓ), deposited at a rate of around 0.1 Å/s. The MoOₓ is an optional layer that provides good hole injection properties.

N,N′-Di(1-naphthyl)-N,N′-diphenyl-(1,1′-biphenyl)-4,4′-diamine (NPB), aluminium tri-quinolate (Alq₃), Cl-BsubPc, chloro hexachloro boron subphthalocyanine (Cl—Cl₆-BsubPc), pentafluoro phenoxy-boron subphthalocyanine (F₅—BsubPc), and/or Cl-ClₙBsubNc were then deposited at a rate of around 1 Å/s. Various combinations were used, as set out in Table 1, below.

The Cl-BsubPc was synthesized according to methods described in G. E. Morse, A. S. Paton, A. Lough, T. P. Bender, Dalton Trans., 39 (2010), pp. 3915-3922, which is herein incorporated by reference in its entirety, and train sublimed to electronic purity. The Cl—Cl₆-BsubPc was synthesized according to methods described in P. Sullivan, A. Duraud, I. Hancox, N. Beaumont, G. Mirri, J. H. R. Tucker, R. A. Hatton, M. Shipman and T. S. Jones, Advanced Energy Materials, 2011, 1, 352-355, which is herein incorporated by reference in its entirety, and train sublimed to electronic purity. The F₅-BsubPc was synthesized according to methods described in H. Gommans, T. Aernouts, B. Verreet, P. Heremans, A. Medina, C. G. Claessens and T. Torres, Advanced Functional Materials, 2009, 19, 3435-3439, which is herein incorporated by reference in its entirety, and train sublimed to electronic purity. Train sublimed material was analyzed by mass spectrometry to confirm that no undesired peripheral chlorination over the BsubPc chromophores was present. The Cl—Clₙ-BsubNc was synthesized according to methods described in J. D. Dang, D. S. Josey, A. J. Lough, Y. Li, A. Sifate, Z.-H. Lu, T. P. Bender, J. Mater. Chem. A, (2016), 4, 24, 9566-9577.

Sublimation-grade Cl-ClₙBsubNc; device grade NPB; device grade Alq₃; device grade MoOₓ; and device grade LiF were obtained from Lumtec. Aluminum (99.999%) was obtained from R. D. Mathis.

After the deposition of NPB, Alq₃, Cl-BsubPc and/or Cl-ClₙBsubNc, the substrates were transferred into the integrated glove box without exposure to atmosphere, and the device mask was exchanged for a 2 mm wide cathode shadow mask. LiF was then deposited at a rate of around 1 Å/s. Aluminum was then deposited at a rate of around 2 Å/s.

OLED pixels were formed by the intersection the 1 mm wide ITO bars with the 2 mm wide aluminum strip, giving each individual device a surface area of 2 mm². Each device included eight pixels; all results with error bars are calculated from an average of the four central pixels.

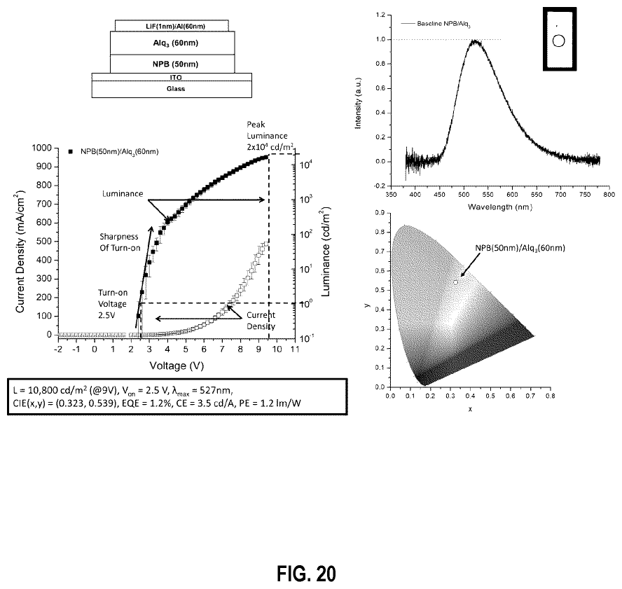

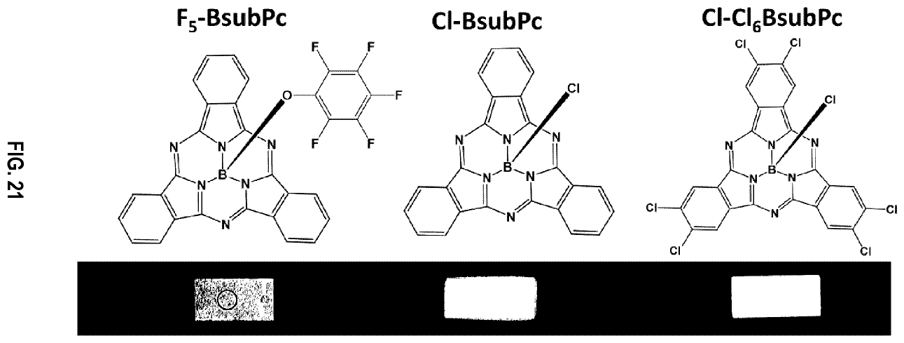

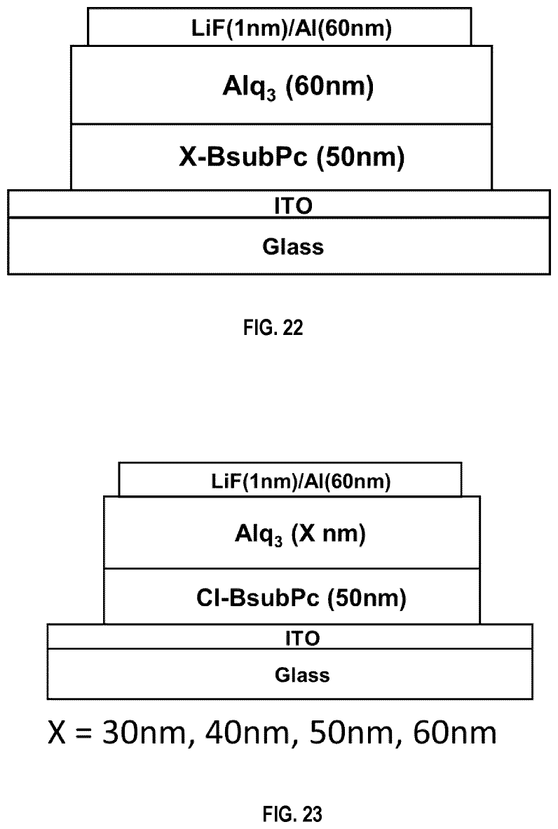

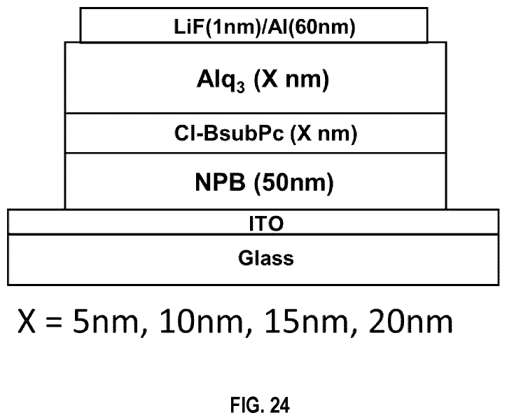

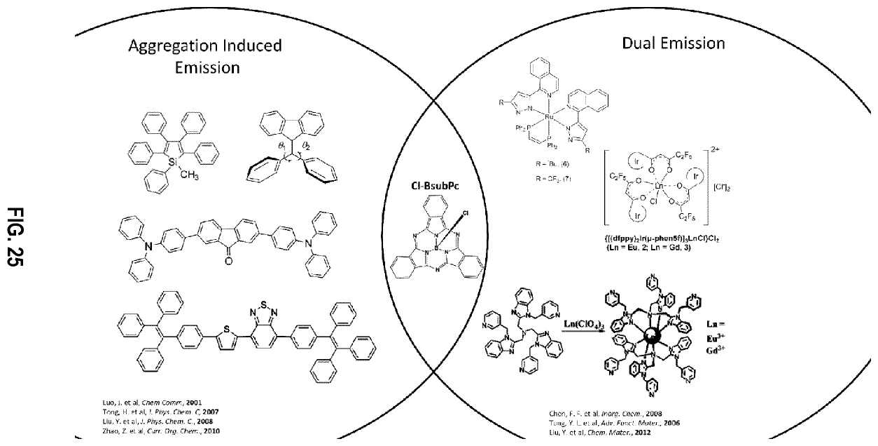

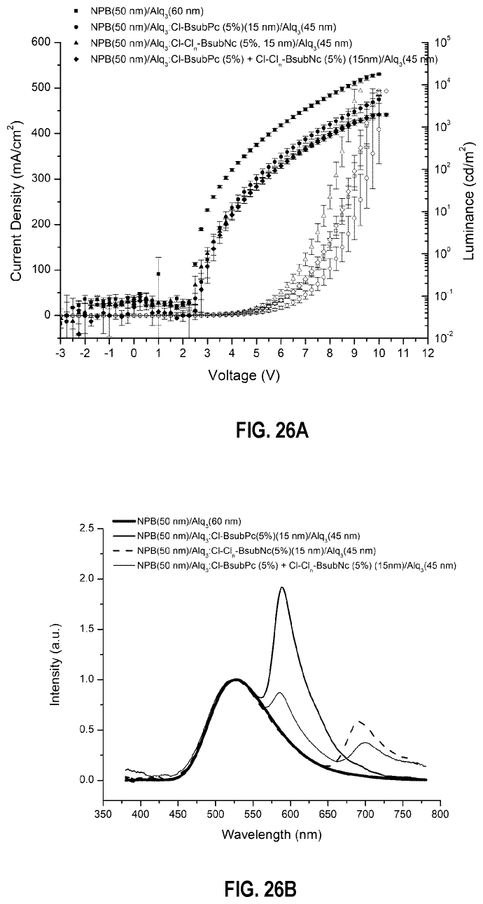

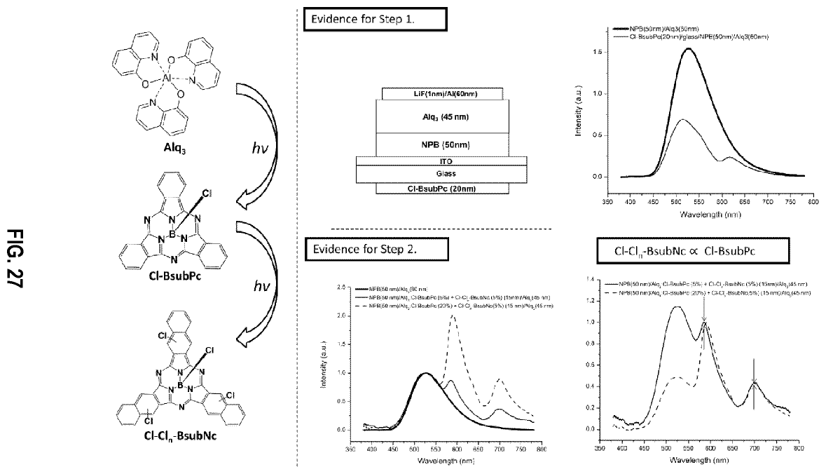

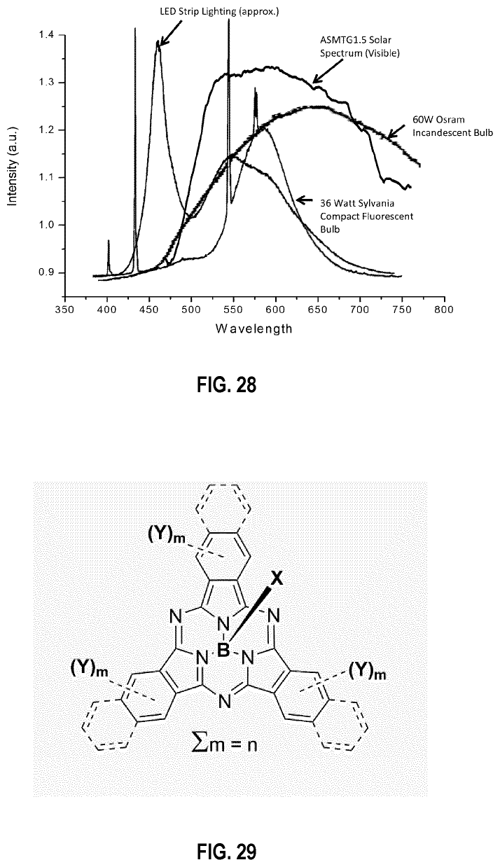

A control device was fabricated without any BsubPc derivative according to the following configuration: glass/ITO (120 nm)/MoOₓ(1 nm)/NPB (50 nm)/Alq₃ (60 nm)/LiF (1 nm)/Al (100 nm). The control device exhibited a bright-green emission. Various properties of the control device is set out in FIG. 20. Various OLED devices were produced by varying the deposition of the BsubPc derivative as set out to Table 1.

TABLE 1
Architecture of Example Devices

| Example Device # | Device Structure | |
|---|---|---|
| Control | NPB (50 nm) | Alq₃(60 nm) |
| A1 | Cl—BsubPc (50 nm) | Alq₃(60 nm) |
| A2 | F₅BsubPc (50 nm) | Alq₃(60 nm) |
| A3 | Cl—Cl₆—BsubPc (50 nm) | Alq₃(60 nm) |
| A4 | Cl—BsubPc (50 nm) | Alq₃(50 nm) |
| A5 | Cl—BsubPc (50 nm) | Alq₃(40 nm) |
| A6 | Cl—BsubPc (50 nm) | Alq₃(30 nm) |

| | | | |
|---|---|---|---|
| A7 | NPB (50 nm) | Cl—BsubPc (5 nm) | Alq₃(60 nm) |
| A8 | NPB (50 nm) | Cl—BsubPc (10 nm) | Alq₃(60 nm) |
| A9 | NPB (50 nm) | Cl—BsubPc (15 nm) | Alq₃(60 nm) |
| A10 | NPB (50 nm) | Cl—BsubPc (20 nm) | Alq₃(60 nm) |
| B1 | NPB (35 nm) | NPB:Cl—BsubPc (5%) (15 nm) | Alq₃ (60 nm) |
| B2 | NPB (35 nm) | NPB:Cl—ClₙBsubNc (5%) (15 nm) | Alq₃ (60 nm) |
| B3 | NPB (50 nm) | Alq₃:Cl—BsubPc (5%) (15 nm) | Alq₃ (45 nm) |
| B4 | NPB (50 nm) | Alq₃:Cl—ClₙBsubNc (5%) (15 nm) | Alq₃ (45 nm) |
| B5 | NPB (50 nm) | Alq₃:Cl—BsubPc (5%) + Cl—ClₙBsubNc (5%) (15 nm) | Alq₃ (45 nm) |
| B6 | NPB (50 nm) | Alq₃:Cl—BsubPc (20%) (15 nm) | Alq₃ (45 nm) |
| B7 | NPB (50 nm) | Alq₃:Cl—BsubPc (20%) + Cl—ClₙBsubNc (5%) (15 nm) | Alq₃(45 nm) |

| | | |
|---|---|---|
| B8 | Cl—BsubPc (50 nm) | Alq₃(60 nm) |
| B9 | Cl—ClₙBsubNc (50 nm) | Alq3(60 nm) |

In Table 1, each layer is separated by column. The thickness and composition of each layer is denoted. The percentages indicate the concentration of the Cl-BsubXc component in the layer on a mass basis.

In Example Devices B1-9, the substrate and electrode layers (i.e. glass/ITO/MoOₓ and LiF/AI layers) are substantially the same as the control device, but the hole transporting layer (HTL) and the electron transporting layer (ETL) comprising NPB and Alq₃, respectively, are modified. In the Example Devices B1-9, the total thickness of the HTL and ETL are controlled to be 50 nm and 60 nm, respectively.

Different doping concentrations were incorporated in order to assess the potential of Cl-BsubPc and Cl-ClₙBsubNc as dopants both alone and co-doped into OLEDs.

### Example 2—OLED Characterization

The electroluminescent performance of each OLED produced in Example 1 was tested in ambient atmosphere immediately after fabrication and without encapsulation. Negligible degradation of device performance was observed over the timescale of characterization, although small non-emissive spots began forming within hours of exposure to atmosphere.

The control luminance and spectra are included in subsequent figures to illustrate the relative performance of subsequent variations on this device architecture. Collected current efficiency (CE), photoluminescent efficiency (PE), external quantum efficiency (EQE), CRI, R9 and CIE1931(x, y) values for Example Devices A1-10 are tabulated in Table 2. Collected current efficiency (CE), photoluminescent efficiency (PE), external quantum efficiency (EQE), CRI, R9 and CIE1931(x, y) values for Example Devices B1-9 are tabulated in Table 3.

Ultraviolet-visible (UV-Vis) spectroscopy was performed using a PerkinElmer Lambda 1050 on solid-state thin films deposited on standard glass microscope slides. Wavelength dependent emission spectra for individual pixels were measured using an Ocean Optics USB4000 Spectrophotometer fed through a fiber-optic cable. Luminance was measured using a Minolta LS-110 Luminance Meter. Driver voltage and device current were measured with a Hewlett-Packard HP4140B pA Meter/DC Voltage Source controlled by custom LabView software. CIE1931(x, y) co-ordinates and CRI values were calculated using ColorCalculator 5.21, available from OSRAM SYLVANIA.

TABLE 2
Collected Luminance, Photoluminescent Efficiency (PE), Current Efficiency
(CE), External Quantum Efficiency (EQE), Color Rendering Index (CRI),
R9 Values, and CIE(1931) (x, y) values for Example Devices A1-10.

| | Luminance at | PE @ 100 | CE @ 100 | | | | | |
|---|---|---|---|---|---|---|---|---|
| | 8 V | cd/m² | cd/m² | EQEₚₑₐₖ | | | | CIE1931 |
| Device | (cd/m²)* | (lm/W) | (cd/A) | (%) | | CRI^{‡} | R9^{‡} | (x, y)^{‡} |
| Control | 8342 ± 1139 | 3.3 ± 0.95 | 3.7 ± 1.1 | 1.2 | (6.8 V) | 41 | −149 | (0.33, 0.54) |
| A1 | 73 ± 9 | 0.07 ± 0.01 | 0.20 ± 0.02 | 0.14 | (8.5 V) | 66 | 8 | (0.31, 0.44) |
| A2 | 14 ± 3 | 0.10 ± 0.02 | 0.30 ± 0.07 | N/A b) | | 64 | 49 | (0.31, 0.48) |
| A3 | N/A b) | 0.02 ± 0.01 | 0.09 ± 0.01 | N/A b) | | 49 | 24 | (0.26, 0.48) |
| A4 | 193 ± 27 | 0.06 ± 0.01 | 0.16 ± 0.02 | 0.20 | (4.5 V) | 31 | −133 | (0.36, 0.47) |
| A5 | 294 ± 19 | 0.05 ± 0.01 | 0.10 ± 0.01 | 0.10 | (5 V) | 26 | −93 | (0.45, 0.38) |
| A6 | 305 ± 7 c) | 0.04 ± 0.01 | 0.07 ± 0.01 | 0.13 | (4 V) | 35 | 13 | (0.53, 0.36) |
| A7 | 1894 ± 90 | 0.78 ± 0.01 | 1.06 ± 0.01 | 0.31 | (6 V) | 55 | −27 | (0.35, 0.53) |
| A8 | 1144 ± 6 | 0.42 ± 0.01 | 0.67 ± 0.02 | 0.30 | (6.75 V) | 66 | 73 | (0.36, 0.51) |
| A9 | 770 ± 89 | 0.23 ± 0.07 | 0.38 ± 0.14 | 0.31 | (5.5 V) | 65 | 68 | (0.35, 0.51) |
| A10 | 468 ± 138 | 0.18 ± 0.03 | 0.32 ± 0.05 | 0.33 | (4 V) | 69 | 26 | (0.36, 0.48) |

Legend:
*average of four pixels
^{‡}values calculated using Osram Sylvania ColorCalculator 5.21

TABLE 3
Collected Luminance, Current Efficiency (CE), Phololuminescent Efficiency (PE), External
Quantum Efficiency (EQE), CRI, R9 and CIE1931(x, y) values for Example Devices

| | Turn on | Luminance | | | | | | | | |
|---|---|---|---|---|---|---|---|---|---|---|
| | Voltage | at 8 V | CEₚₑₐₖ | PEₚₑₐₖ | CE | PE | EQEₚₑₐₖ | | | CIE1931 |
| Device | (V) | (cd/m²)* | (cd/A)\hat{ } | (lm/W)\hat{ } | (cd/A)^{†} | (lm/W)^{†} | (%)^{‡} | CRI^{‡} | R9 | (x, y) |
| Control | 2.5 | 8342 ± 1140 | 3.31 ± 0.32 | 4.03 ± 1.57 | 3.58 ± 0.94 | 1.97 ± 0.23 | 1.37 | 41 | −149 | (0.341, 0.557) |
| | | | | | 3.17 ± 0.30 | 1.49 ± 0.118 | | | | |
| B1 | 3.5 | 896.3 ± 140 | 0.97 ± 0.04 | 0.34 ± 0.04 | 0.71 ± 0.15 | 0.33 ± 0.03 | 0.39 | 48 | −114 | (0.559, 0.448) |
| | | | | | 0.84 ± 0.06 | 0.30 ± 0.02 | | | | |
| B2 | 3.0 | 552.1 ± 26 | 1.00 ± 0.12 | 0.59 ± 0.25 | 0.63 ± 0.08 | 0.31 ± 0.04 | 0.41 | 39 | −136 | (0.339, 0.554) |
| | | | | | 0.85 ± 0.11 | 0.30 ± 0.04 | | | | |
| B3 | 3.0 | 1145 ± 220 | 1.21 ± 0.08 | 1.21 ± 0.22 | 1.16 ± 0.02 | 0.66 ± 0.02 | 0.51 | 65 | −74 | (0.482, 0.366) |
| | | | | | 1.12 ± 0.01 | 0.46 ± 0.01 | | | | |
| B4 | 3.0 | 711.9 ± 80 | 0.28 ± 0.01 | 0.24 ± 0.01 | 0.24 ± 0.001 | 0.13 ± 0.01 | 0.16 | 41 | −139 | (0.320, 0.544) |
| | | | | | 0.27 ± 0.01 | 0.10 ± 0.01 | | | | |
| B5 | 3.25 | 629.7 ± 79 | 0.40 ± 0.02 | 0.26 ± 0.02 | 0.35 ± 0.02 | 0.20 ± 0.01 | 0.20 | 57 | −93 | (0.366, 0.507) |
| | | | | | 0.38 ± 0.02 | 0.14 ± 0.01 | | | | |
| B6 | 3.5 | 314.7 ± 120 | 1.28 ± 0.16 | 0.93 ± 0.68 | 1.19 ± 0.38 | 0.57 ± 0.18 | 0.54 | 63 | −89 | (0.513, 0.444) |
| | | | | | 1.18 ± 0.10 | 0.38 ± 0.03 | | | | |
| B7 | 3.25 | 358.1 ± 23 | 0.86 ± 0.42 | 0.81 ± 0.42 | 0.50 ± 0.08 | 0.24 ± 0.04 | 0.18 | 70 | −54 | (0.458, 0.470) |
| | | | | | 0.43 ± 0.06 | 0.14 ± 0.02 | | | | |
| B8 | 3.75 | 250.5 ± 29 | 0.34 ± 0.04 | 0.313 ± 0.05 | 0.29 ± 0.06 | 0.13 ± 0.02 | 0.18 | 66 | 8 | (0.318, 0.385) |
| | | | | | 0.25 ± 0.01 | 0.08 ± 0.01 | | | | |
| B9 | 3.5 | 792.1 ± 130 | 0.24 ± 0.01 | 0.09 ± 0.01 | 0.22 ± 0.01 | 0.09 ± 0.004 | 0.09 | 21 | −262 | (0.231, 0.568) |
| | | | | | — | — | | | | |

Legend:
*average of four pixels
\hat{ }peak values measured when luminance exceeded 1 cd/m²
^{†}values measured at L = 100 cd/m² and L = 1000 cd/m²
^{‡}values calculated using Osram Sylvania ColorCalculator 5.21

### Example 3—BsubPc Derivatives in OLED Devices

OLEDs were produced to investigate the potential use of the following BsubPc derivatives: chloro boron subphthalocyanine (Cl-BsubPc), pentafluoro phenoxy-BsubPc (F₅—BsubPc), and chloro hexachloro boron subphthalocyanine (Cl—Cl₆-BsubPc). These molecules have previously been studied as optical photovoltaics (OPVs), and their synthesis is known to skilled persons. Although these materials are known for use in OPVs, the selection criteria for use therein is based on the material's ability to absorb photons and conduct electrons, whereas OLED materials are selected based on their ability to conduct electrons and emit photons. Further, OPV materials typically do not emit photons under the conditions suitable for operating OLEDs.

It was previously shown in M. G. Helander, G. E. Morse, J. Qiu, J. S. Castrucci, T. P. Bender and Z.-H. Lu, ACS Applied Materials & Interfaces, 2010, 2, 3147-3152, which is herein incorporated by reference in its entirety, that by doping F₅-BsubPc into 4,4′-N,N′-dicarbazole-biphenyl (CBP), tris-(8-hydroxy-quino-lato)aluminum (Alq₃), and 1,3,5-Tris(N-phenylbenzimidazole-2-yl)benzene (TPBi), the resulting OLED would have a unique and relatively narrow emission from F₅—BsubPc in the orange region of the spectrum. However, these OLEDs were engineered to reduce the secondary emission peak at ˜710 nm resulting from aggregate emission to attempt to preserve color purity. The aggregate emission may be used to create white organic light emitting diodes (WOLEDs) with reduced numbers of different electroluminescent compounds.

Given the known dual functionality of BsubPcs as both hole- and electron-transporting materials, and the known aggregate emission at 710 nm, the NPB hole transporting layer (HTL) in the control device was replaced with a selection of BsubPcs in order to understand the role of aggregation in the emission profile of OLEDs with HTLs of varying BsubPc compositions.

OLED devices having the following structure were fabricated and characterized: glass/ITO (120 nm)/X-BsubPc (50 nm)/Alq₃ (60 nm)/LiF (1 nm)/Al (60 nm) where X═Cl (Example Device A1), F₅ (Example Device A2) and Cl—Cl₆ (Example Device A3). A schematic diagram showing the structure of these devices is shown at FIG. 2. A consistent HTL thickness of 50 nm was selected in order to make devices directly comparable to the control device.

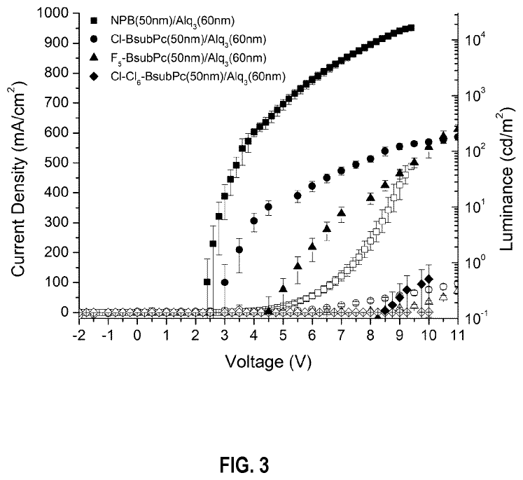

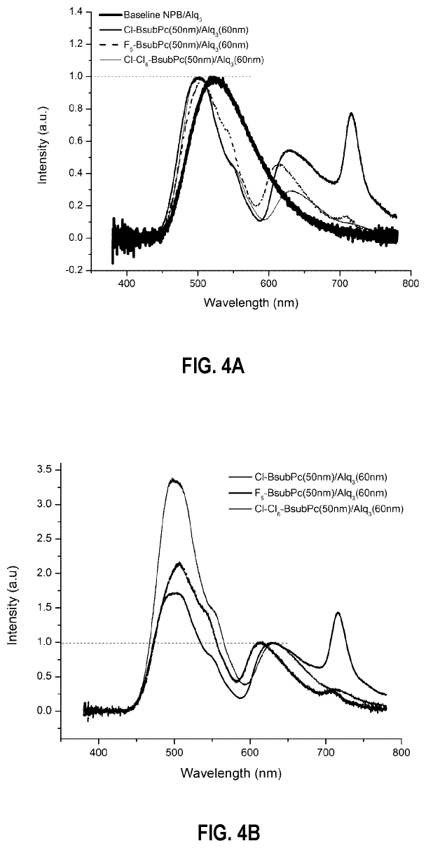

The current-voltage-luminance (JVL) and spectral plots for Example Devices A1-3 are illustrated along with those of the control device in FIGS. 3, 4A and 4B, respectively. A summary of performance characteristics for these devices including photoluminescence efficiency (PE), current efficiency (CE), external quantum efficiency (EQE) CRI, R9 and CIE1931 (x, y) coordinates are tabulated in Table 2. A diagram showing the color of the light underneath each of their respective BsubPc derivative is shown in FIG. 21.

It was observed that the peak luminance of the NPB/Alq₃ control device outperforms the best of Example Devices A1-A3 by about two orders of magnitude. Cl-BsubPc, F₅—BsubPc, and Cl—Cl₆-BsubPc OLEDs have turn-on voltages of 2.8 V, 4.5 V, and, 8.5 V, respectively, in comparison to 2.4 V for the control device. All three of Example Devices A1-3 emitted green, or greenish-white light, correlating with the degree of X-BsubPc fluorescence contribution. In addition to the green/white light emitted from the 2 mm² OLED pixel, red light was observed being wave-guided through, and transmitted out the sides of the glass substrate. All three of Example Devices A1-3 had significantly lower PE and CE values than the control device. This was expected as the structures tested were not optimized, nor do they have the advantage of additional injection or exciton blocking layers. F₅—BsubPc had the highest PE and CE values, however due to its low BsubPc electroluminescence contribution, F₅—BsubPc was considered unsuitable for white OLEDs going forward.

With regards to CRI values, a general improvement relative to the control device was observed, which is consistent with a general broadening of the spectral output. Likewise, the dramatic improvement in R9 value relative to control device was expected given the introduction of a red emitting material.

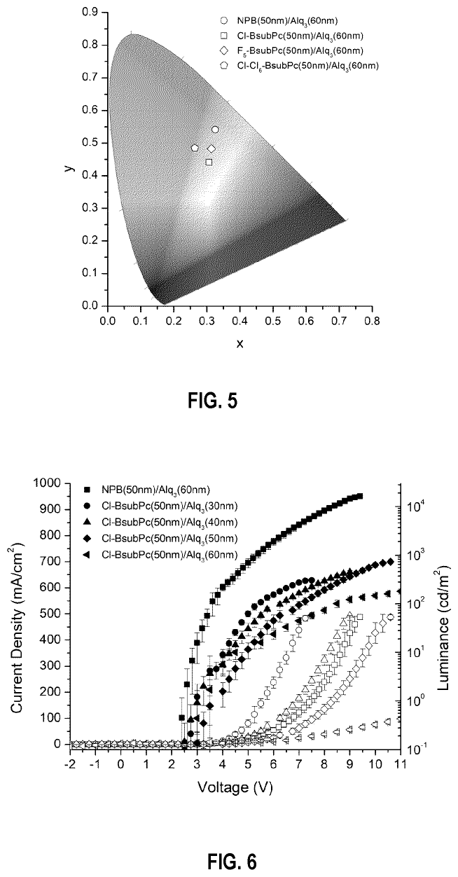

However, it was not immediately clear why F₅-BsubPc and Cl—Cl₆-BsubPc would yield higher overall R9 values, given that their proportional contribution in the red end of the spectrum was significantly lower compared to Cl-BsubPc. In order to further quantify the color of Example Devices A1-3, device spectra were converted to CIE1931 (x, y) coordinates. The CIE co-ordinates for Example Devices A1-3 are plotted in FIG. 5, along with those of the NPB/Alq₃ control device. Example Devices A1-3 showed “whiter” emission than the control device due to the contribution from the BsubPc derivative chromophore. Example Device A1 emitted light with a CIE coordinate of (0.31, 0.44), which falls closer to the CIE standard for white than Example Devices A2 and A3.

Based on luminance data, turn-on voltages, and CRI values, Cl-BsubPc appeared to be a preferred WOLED candidate among the three BsubPc derivatives initially examined. As shown in FIG. 4A, all three BsubPc derivatives showed a contribution to the emission spectra when acting as an HTL. This is not generally the case of HTLs. Without wishing to be bound by theory, it is believed that electron-hole recombination is taking place in both the BsubPc layer and in the Alq₃ layer since BsubPc derivatives have exhibited the ability to transport both electrons and holes. The fluorescence contributions for all BsubPc HTLs showed two peaks of varying proportion, one near the characteristic orange absorption peak of the BsubPc chromophore in the vicinity of 600 nm and a second red peak or shoulder around 710 nm.

It is believed that the 710 nm contribution is the result of inter-aggregate exciton energy transfer via non-radiative process(es). These may include energy transfer to BsubPc aggregates from lone molecules, or potentially excitation by Förster resonant energy transfer (FRET) from the Alq₃ layer. BsubPc aggregates of any size may experience a net increase in conjugation via intermolecular π-πstacking, which may explain the observed red shift in emission.

Further, a significant blue-shift in the emission of the Alq₃ emission peak was observed in Example Devices A1-A3 relative to the emission from the NPB/Alq₃ control device. When the photo-physical properties of the BsubPc chromophore (shown in FIG. 1) are compared to the normalized emission spectra of the control device (shown in FIG. 4A, black line), a zone of overlap in the vicinity of 520 nm was observed.

This shift in emission is likely a result of the absorption of the longer wavelength fraction of the Alq₃ emission profile by the shorter wavelength absorption band of the BsubPc chromophore as the Alq₃ emission travels through the BsubPc layer. Photoluminescence data shown in FIG. 1 showing that Cl-BsubPc undergoes stimulated photoluminescence under radiation in the vicinity of 520 nm appears to corroborate this theory. This shifting process is also consistent with experimental work by T. Plint, B. H. Lessard and T. P. Bender, Journal of Applied Physics, 2016, 119, 145502, which is hereby incorporated reference in its entirety, incorporating metal phthalocyanines (MPcs) as HTLs in OLEDs.

### Example 4—Varying Thickness of Alq₃ Layer

Expanding on Example 3, a series of WOLEDs with a Cl-BsubPc HTL, but varying thicknesses of the Alq₃ layer were constructed (Example Devices A4-6) to see if the location of the recombination zone could be controlled, as a method for tuning the color spectrum.

The generic device structure employed was as follows: glass/ITO (120 nm)/Cl-BsubPc (50 nm)/Alq₃ (X nm)/LiF (1 nm)/Al (60 nm), where X was 60 nm (Example Device A1), 50 nm (Example Device A4), 40 nm (Example Device A5), or 30 nm (Example Device A6).

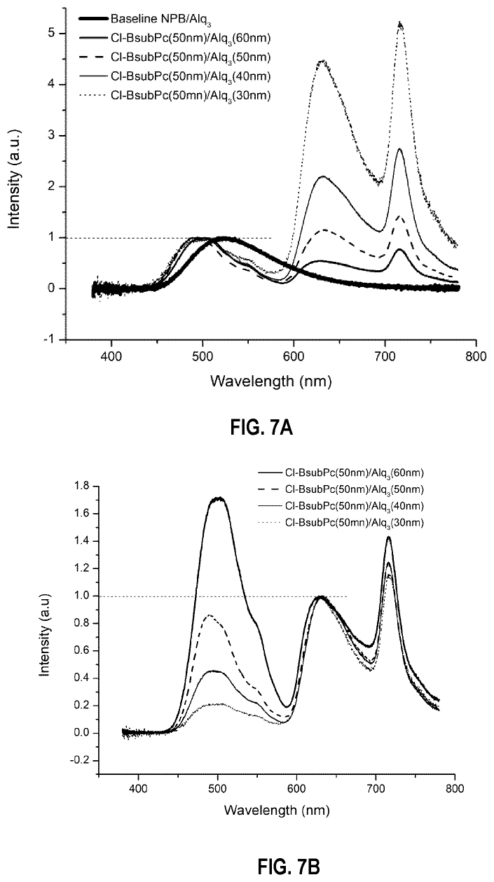

The current-voltage-luminance (JVL), and spectral plots for these devices are shown along with those of the control device in FIG. 6 and FIG. 7, respectively. These devices showed consistent turn-on voltages between 2.5 V and 3.0 V, and peak luminance roughly an order of magnitude less than that of the NPB/Alq₃ control device.

At 8 V, luminance of Example Devices A1 and A4-6 varied between 73±9 cd/m² and 305±7 cd/m², for X=60 nm (Example Device A1) and X=30 nm (Example Device A6), respectively. This trend demonstrated increasing total luminance as a function of diminishing Alq₃ layer thickness.

Conversely, PE and CE values diminish as a function of shrinking Alq₃ thickness, as shown in Table 2. Without wishing to be bound by theory, it is believed that this was due to the lower fluorescence efficiency of Cl-BsubPc as compared to Alq₃; but as the Alq3 layer becomes thinner, better charge balancing at the interface is achieved, increasing total luminance.

Additionally, a smaller proportion of total luminance comes from the Alq₃ layer shifting the net emission color. As the thickness of the Alq₃ layer was reduced, the overall the light emitted was observed to be “warmer”.

FIG. 7A shows the proportion of emission from the BsubPc chromophore normalized relative to the emission from the Alq₃ ETL. It is believed that the increase in total brightness was the result of increased contribution from the Cl-BsubPc layer.

FIG. 7B shows that the proportion of red aggregate emission varies in proportion relative to the primary BsubPc emission peak. It was observed that a diminution in Alq₃ emission correlates with a reduction in proportional Cl-BsubPc aggregate emission. This suggests that an energetic absorption/re-emission interaction between the Alq₃ emission and the Cl-BsubPc chromophore is possible. Previous studies by M. G. Helander, G. E. Morse, J. Qiu, J. S. Castrucci, T. P. Bender and Z.-H. Lu, ACS Applied Materials & Interfaces, 2010, 2, 3147-3152, which is hereby incorporated by reference, with F₅-BsubPc have shown that there is Förster resonant energy transfer (FRET) with Alq₃. While this mechanism may be responsible for some of the BsubPc aggregate emission, traditional electron/hole recombination and inter-aggregate energy reduction may also play a role in the emissions around 710 nm. Also, a slight but consistent narrowing of the Cl-BsubPc emission peak as a function of diminishing Alq₃ thickness was observed.

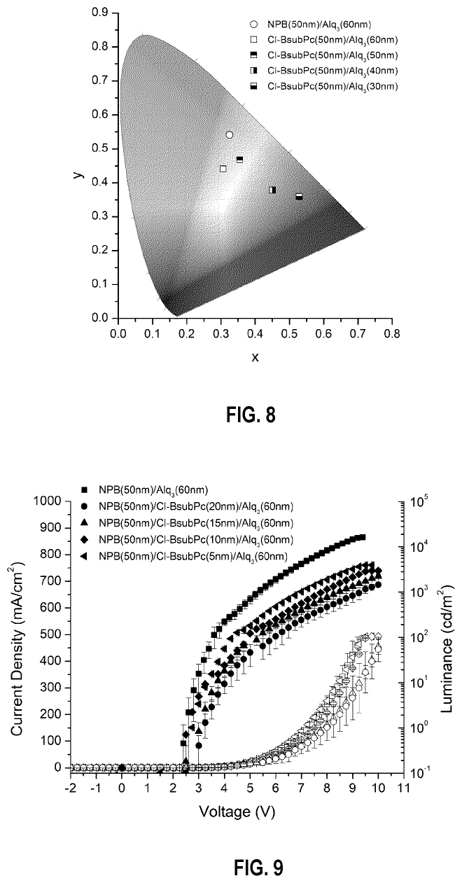

Example Devices A1 and A4-A6 emitted greenish-white light shifting to warm white light as the Alq₃ layer became thinner. The CIE co-ordinates for these devices are plotted in FIG. 8, along with those of the control device. The overall appearance of the emission, shifted from greenish-white (0.31, 0.44) towards a warm orange white (0.53, 0.36), show that the color of the OLED emission may be tuned by modifying relative film thickness. This is consistent with the observations of the emission spectra of FIG. 7A. These results demonstrate the potential of Cl-BsubPc in WOLEDs as an HTL that doubles as a dual-emitting layer.

With regards to CRI values, devices with relatively thinner ETL (Example Devices A4-A6) exhibited weaker performance relative to Example Device A1. Additionally, and somewhat surprisingly, the R9 for Example Device A4 showed a sharp drop as compared to Example Device A1, in spite of rising proportional contribution in the red region of the spectrum. Following this sharp drop, R9 values rose more expectedly with thinner ETL thickness until slightly exceeding that of the Example Device A1. Curiously, to the naked eye, each of these devices gave off a warm white light, and yet showed lower CRI and R9 values compared to Cl—Cl₆-BsubPc device (Example Device A3) and F₅—BsubPc device (Example Device A2), which to the observer appeared pale green.

### Example 5—OLEDs with BsubPc Derivative Interlayer

While the emission characteristics of bilayer OLEDs are of interest, the substitution of NPB with Cl-BsubPc resulted in a drop in peak luminance. Also, reducing the total thickness of the Alq₃ layer resulted in a marginal increase in peak luminance, but not sufficient to cross exceed 1000 cd/m². Since Cl-BsubPc is exhibited orange and red contribution to a device spectrum, its use as an interlayer near the recombination zone of a standard NPB/Alq₃ device was tested.

OLEDs with the following generic structure were: glass/ITO (120 nm)/NPB (50 nm)/Cl-BsubPc (X nm)/Alq₃ (60 nm)/LiF (1 nm)/Al (60 nm), where X was 5 nm (Example Device A7), 10 nm (Example Device A8), 15 nm (Example Device A9), or 20 nm (Example Device A10).

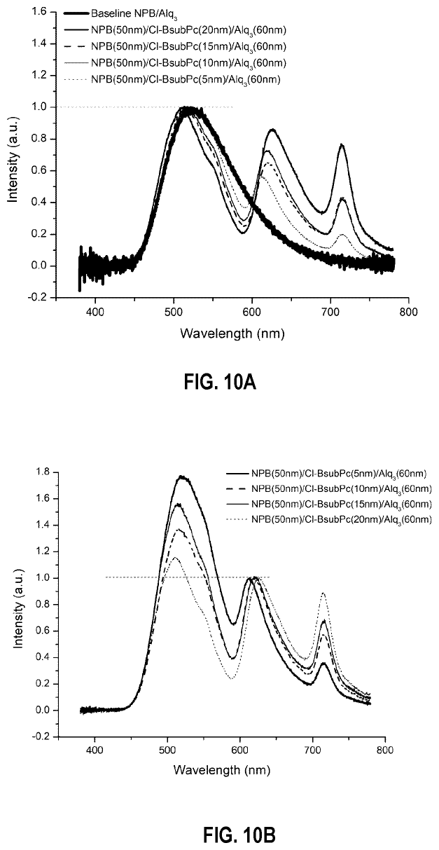

The current-voltage-luminance (JVL), and spectral plots for these devices are illustrated along with those of the control device in FIG. 9 and FIG. 10 respectively. Devices showed consistent turn on voltage of 2.5 V, and peak luminance values on the same order of magnitude of the control device.

At 8 V, device luminance varied between 1894±90 cd/m2 and 468±138 cd/m2 for X=5 nm and X=20 nm, respectively. Using the control device (X=0) as a point of comparison, having luminance at 8 V of 8342±1139 cd/m², it was observed that peak luminance decreased a function of increasing Cl-BsubPc layer thickness.

Both PE and CE values for interlayer devices were roughly an order of magnitude larger than for bi-layer devices yet decreased as a function of increasing Cl-BsubPc thickness.

FIG. 10A shows the proportion of emission from the BsubPc chromophore normalized relative to the emission from the Alq₃ ETL. An increase in orange contribution around 610 nm was observed with increasing Cl-BsubPc interlayer thickness.

The proportion of aggregate emission relative to the primary BsubPc emission peak is shown in FIG. 10B. Between the 5 nm and 20 nm thicknesses, an increase in red emission around 710 nm was observed, corresponding with increasing Cl-BsubPc thickness relative to Alq₃ thickness.

A contradiction appeared to be presented: with Example Devices A4-6 it was observed that rising aggregate emission correlates with a decreasing ratio of Cl-BsubPc/Alq₃; however, in Example Devices A7-A10, the trend is reversed. Without wishing to be bound by theory, it is believed that the addition of an interlayer between an HTL and an ETL alters the location of the recombination zone. Based on the combined emission Alq₃ and Cl-BsubPc emission, the recombination zone likely straddles the Cl-BsubPc/Alq₃ interface.

Given the degree of overlap between the BsubPc solid state absorption peak and the primary BsubPc emission peak, a high degree of intermolecular quenching amongst Cl-BsubPc molecules would be expected. If the emission of the primary BsubPc peak is determined by a charge hopping mechanism, there may be a threshold Cl-BsubPc thickness beyond which intermolecular quenching limits the extraction of any further BsubPc emission. If aggregate emission were dominated by FRET, then Cl-BsubPc thickness alone would determine the degree of aggregate emission.

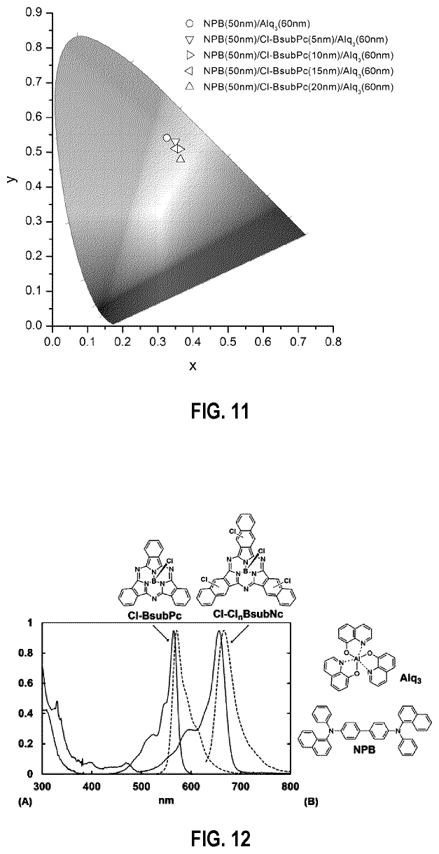

The CIE co-ordinates for these OLEDs are collected in FIG. 11, the apparent color of these interlayer OLEDs ranged through various shades of orange-white. It was observed that Cl-BsubPc layer thickness correlates with increasing overall warmth of color from (0.35, 0.53) to (0.36, 0.48), for X=5 nm and X=20 nm, respectively. However, compared with FIG. 8, the color space accessible to interlayer devices (Example Devices A7-A10) was narrower. This suggests that the use of even a relatively thin interlayer of neat Cl-BsubPc may effect a useful shift in overall OLED color, at the cost of peak luminance.

The CRI values for these interlayer devices showed encouraging results. Example Device A10 exhibited a CRI of 69, while Example Device 8 exhibited a CRI of 66 and R9 of 73, both improvements relative to the non-interlayer devices. For comparison, the CRI and R9 values for a typical commercial white inorganic LED, and compact fluorescent tube are (82, 22) and (82, <0), respectively.

On the basis of these findings, it was shown that BsubPc derivatives, and Cl-BsubPc in particular, may potentially be useful as emitters in WOLEDs, especially for indoor task lighting. The combined orange-red emission through combined fluorescence, and aggregate emission may provide good R9 values in potential commercial WOLEDs.

### Example 6—Doping of NPB and Alq₃ with Cl-BsubPc and Cl—Clₙ BsubNc

In order to assess four potential combinations of host-dopant emitter systems with Cl-BsubPc or Cl-ClₙBsubNc dopants, four OLEDs having the following configurations were fabricated: glass/ITO (120 nm)/MoOₓ (1 nm)/NPB (35 nm)/NPB:Cl-BsubXc (5%) (15 nm)/Alq₃ (60 nm)/LiF (1 nm)/Al (100 nm) and glass/ITO (120 nm)/MoOₓ (1 nm)/NPB (50 nm)/Alq₃:Cl-BsubXc (5%) (15 nm)/Alq₃ (45 nm)/LiF (1 nm)/Al (60 nm), where Cl-BsubXc is either Cl-BsubPc or Cl-ClₙBsubNc (see FIG. 13B). These correspond to Example Devices B1-4.

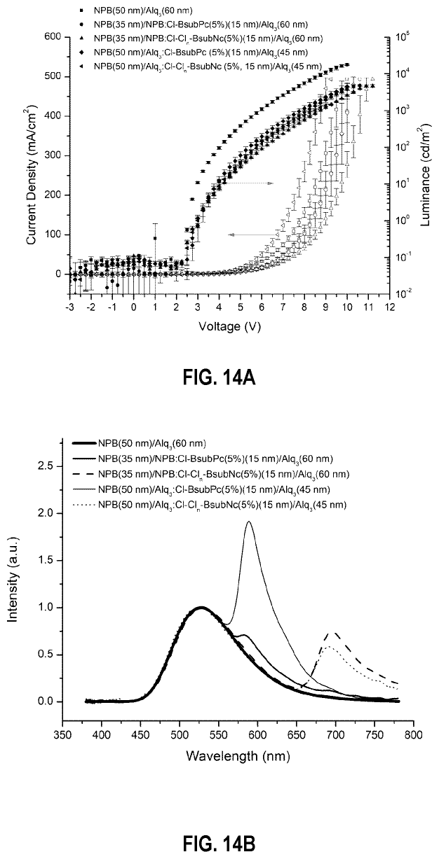

FIG. 14A and FIG. 14B show the average current density (open shapes), luminance (closed shapes) and spectral emission (solid lines) for Example Devices B1-4. Other properties of Example Devices B1-4 are shown on Table 3. These devices showed generally similar turn on voltage and luminance performance; average luminance values at 8 V were all within one order of magnitude of one another. Spectral outputs diverged significantly depending on architecture and material used.

Example Devices B1-4 showed some combined emission from both the Alq₃ and the two emissive compounds, Cl-BsubPc and Cl-ClₙBsubNc, with Cl-BsubPc showing strong characteristic electroluminescence around 590 nm when doped into both NPB and Alq₃.

Alq₃ demonstrated better host material properties for Cl-BsubPc than NPB. Without wishing to be bound by theory, it is believed that this was largely due to better host-dopant band alignment. However, since the emission spectra of Alq₃ partially overlaps with the absorption spectra of Cl-BsubPc, it is speculated that there was additional photonic energy transfer within the Alq₃ layer.

Example Devices B1 and B2 (i.e. those fabricated with BsubPc derivatives doped into NPB) produced OLEDs that emitted an overall green light and relatively lower peak luminance, PE, and CE values. In contrast, Example Devices B3 and B4 (i.e. those fabricated with BsubPc derivatives doped into Alq₃) produced OLEDs that emitted a strong warm-white light, with a luminance of 896±138 cd/m² at 8 V and peak PE and CE values, at 1.22±0.08 cd/A and 1.22±0.22 lm/W, respectively.

Interestingly, the amount of Cl-ClₙBsubNc emission observed when NPB was used as a host material was slightly higher than when Cl-ClₙBsubNc was doped into Alq₃. This may be explained by the host-dopant architecture, where excitons are transferred from the host to the dopant by direct charge trapping.

### Example 7—Doped and Neat Layers of Cl-BsubPc and Cl-ClₙBsubNc

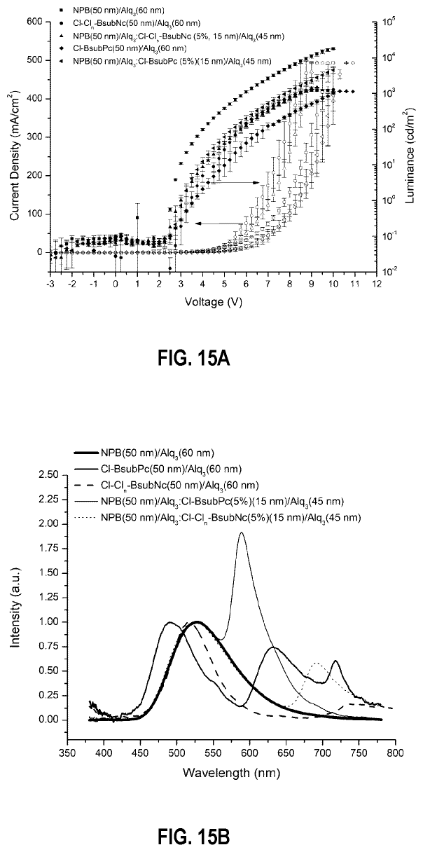

In order to further compare the properties of Cl-BsubPc and Cl-ClₙBsubNc in OLEDs, neat bi-layer devices were fabricated with the generic architecture of: glass/ITO (120 nm)/MoOₓ (1 nm)/Cl-BsubXc (50 nm)/Alq₃ (60 nm)/LiF (1 nm)/Al (100 nm), where Cl-BsubXc is either Cl-BsubPc or Cl—Clₙ BsubNc (e.g. Example Devices B8 and B9). The current density, luminance output and (open shapes), luminance (closed shapes) and spectral emission (solid lines) for these devices are shown in FIGS. 15A and 15B. The corresponding PE, CE, EQE CRI, R9 and CIE1931(x,y) values for these devices are collected in Table 3.

The doped and neat film Cl-BsubPc OLEDs (Example Devices B3 and B8) had a luminance at 8 V of 1145±220 cd/m² and 250±29 cd/m², respectively; almost a full order of magnitude difference. By comparison, doped and neat film Cl-ClₙBsubNc OLEDs (Example Devices B4 and B9) had luminance at 8 V of 712±80 cd/m² and of 792±130 cd/m², respectively. Interestingly, neat-film OLEDs incorporating Cl-ClₙBsubNc showed greater luminance performance than those using Cl-BsubPc.

Example Devices B3, B4, B8 and B9 showed almost identical turn on voltages, between 3.0 V and 3.75 V. In terms of spectral profile, significant variation between doped and neat films was observed. Neat films with Cl-ClₙBsubNc exhibited higher overall luminance than neat films with Cl-BsubPc. Without wishing to be bound by theory, it is believed that, based on HOMO levels, neat films of Cl-ClₙBsubNc have better hole injection properties than neat films of Cl-BsubPc.

Further, it was observed that Cl-BsubPc showed stronger fluorescent contribution in doped films. Cl-BsubPc exhibits a tendency to self-quench, and the host material reduces this effect. In contrast, the spectral contribution of Cl-ClₙBsubNc was remained consistent between doped and neat films. Peak emission wavelengths for devices with Cl-BsubPc and Cl-ClnBsubNc were observed around 740 nm and 690 nm, respectively. The shift was attributed to the self-quenching of shorter emissive wavelengths in the neat film, resulting in an apparent peak shift.

For Cl-BsubPc, the difference between doped and neat films (Example Devices B3 and B8, respectively) was pronounced. Example Device B3 showed a single characteristic BsubPc emission peak centered at 588 nm whose maximum intensity almost doubled that of the host Alq₃ peak. By contrast, Example Device B8 showed dual emission, with primary and aggregate emission peaks centered at 630 nm and 717 nm, respectively. It is noted that the emission peak in FIG. 4B with apparent peak around 485 nm (pink line) comes from fluorescent emission from the Alq₃ layer. The peak appears to be shifted as a result of its partial light absorption by the neat Cl-BsubPc layer (see FIG. 12).

No aggregation induced emission was observed for Cl-BsubPc at 5% doping concentration (Example Device B3). Additionally, the use of Cl-BsubPc diluted in Alq₃ causes a lower degree of quenching of the Alq₃ emission, as evidenced by the negligible peak-shifting relative to the control device shown in FIG. 15B.

Both devices showed a strong white, or warm-white emission, demonstrating the diversity of architectures into which Cl-BsubPc can be integrated to obtain a white emitting OLED. As shown by the difference in relative intensity of the primary Cl-BsubPc peaks in neat and doped devices (Example Devices B3 and B8), a portion of the emissions from Alq₃ is captured by the BsubPc molecules and photons emitted from individual BsubPc molecules are down-converted by aggregates to produce the secondary peak.

### Example 8—Energy Transfer Mechanisms of Cl-BsubPc

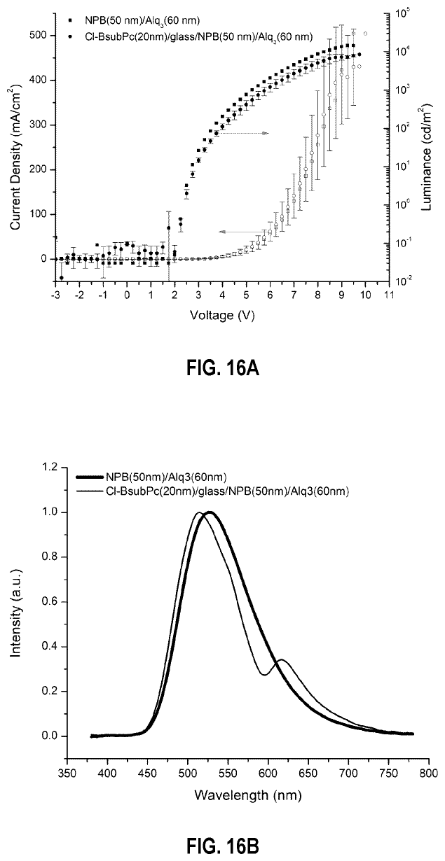

To test whether energy transfer could be effectuated by purely photonic means, rather than by exciton transfer, OLEDs with the following configuration were fabricated: X/glass (1 mm)/ITO (120 nm)/NPB (50 nm)/Alq₃ (60 nm)/LiF (1 nm)/Al (100 nm), where X was either 20 nm of neat Cl-BsubPc, or bare glass. The current density, luminance and spectral output of these devices are shown in FIGS. 16A and 16B, respectively.

Total luminance at 8 V was slightly diminished with the addition of Cl-BsubPc to the underside of the device film, indicating that emission from the Alq₃ layer was being absorbed by the Cl-BsubPc layer. From FIG. 16B, it was observed that the emission from Alq₃ layer is absorbed and re-emitted by the electrically isolated Cl-BsubPc layer. No aggregate emission was observed from the 20 nm neat Cl-BsubPc film in these OLED configurations. This suggests that aggregation induced emission observed in the other devices may be due to an excitonic energy transfer mechanism, such as Förester Resonance Energy Transfer (FRET) or direct charge trapping within a coherent aggregated solid film, rather than a photonic process that could occur through glass.

The spectra of the doped Cl-BsubPc devices in FIG. 14B (Example Device B1 and B3) show good coverage of the visible spectra, but could be brought into closer alignment with the spectral fingerprint of a black body radiator or incandescent lighting element by strengthening the emission coverage in the red end of the visible spectra.

### Example 9—Aggregate Effects of Cl-BsubPc

To test the potential of Cl-ClₙBsubNc as a red emitter, to cover the part of the spectrum not well covered by Cl-BsubPc, OLEDs having co-doped Cl-BsubPc and Cl-ClnBsubNc were produced (Example Device B5, for example) to examine energy transfer processes. However, since the aggregation emission spectra of Cl-BsubPc and the native emission of Cl-ClₙBsubNc are closely aligned, the possibility of aggregation induced emission from Cl-BsubPc in doped films was examined. It was presumed that aggregation is a concentration dependent process and that at higher doping concentrations the onset of aggregation induced emission might be observed for 20% Cl-BsubPc. Accordingly, OLEDs were produced with the architecture: glass/ITO (120 nm)/MoOₓ (1 nm)/NPB (50 nm)/Alq₃:Cl-BsubPc (20%) (15 nm)/Alq₃ (45 nm)/LiF (1 nm)/Al (100 nm) (Example Device B6).

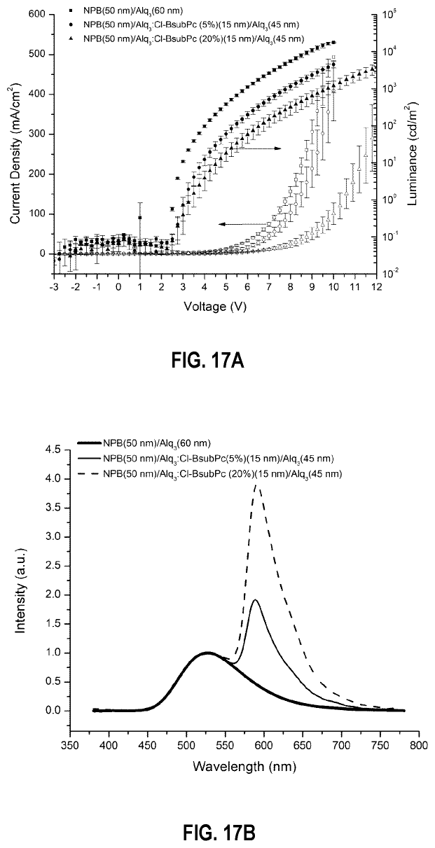

The current density and luminance, and spectral output of Example Device B6 are compared to control results (Control Device and Example Device B1) and are collected in FIGS. 17A and 17B, respectively. The corresponding PE, CE, EQE CRI, R9 and CIE1931(x,y) values for these devices are collected in Table 3.

Luminance performance was slightly diminished for the device doped at 20% (Example Device B6) relative to the device doped at 5% (Example Device B3), which was attributable to increased direct charge trapping in the Alq₃ layer by the Cl-BsubPc dopant and subsequently, increased non-radiative quenching. With regards to the spectral output, while there was a slight shoulder in the vicinity of 700 nm in Example Device B6, there is no obvious peak, suggesting that at 20% doping concentration Cl-BsubPc aggregates are either not present, or are present in such reduced quantities that they play a negligible role in fluorescent emission.

### Example 10—Cl-ClₙBsubNc as a Red Emitter

OLEDs with the following architecture were fabricated to investigate co-doped Cl-BsubPc and Cl-ClₙBsubNc: glass/ITO (120 nm)/MoOₓ (1 nm)/NPB (50 nm)/Alq₃:Cl-BsubPc (X %)+Cl-ClnBsubNc (5%) (15 nm)/Alq₃ (45 nm)/LiF (1 nm)/Al (100 nm), where X is either 5%, or 20% (Example Devices B5 and B7, respectively).

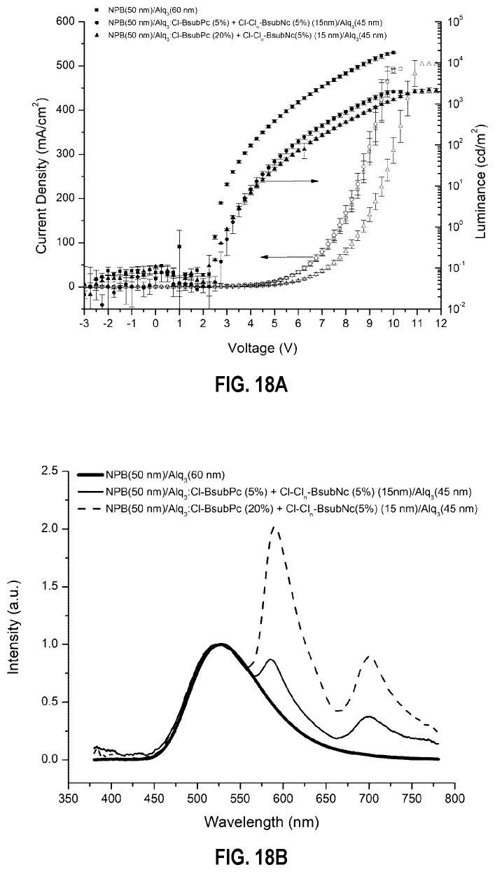

The current density, luminance and spectral output of these devices are compared to control results and are collected in FIGS. 18A and 18B, respectively. The corresponding PE, CE, EQE CRI, R9 and CIE1931(x,y) values for these devices are collected in Table 3.

The luminance output was observed to diminish slightly with the increasing concentration of Cl-BsubPc. This appeared consistent with the results shown in FIG. 17A. It is inferred from the spectral output of these devices that the spectral contribution from Cl-ClₙBsubNc in a co-doped system is strongly dependent on the emission contribution of the Cl-BsubPc dopant.

Given the overlap between the emission profile of Cl-BsubPc and the absorption profile of Cl-ClₙBsubNc and the high degree of congruity between the spectra when normalized relative to the Cl-BsubPc contribution, it is speculated that energy was transferred from Cl-BsubPc to Cl-ClₙBsubNc molecules. Since these materials are thought to be homogeneously mixed in the Alq₃ layer, it is possible that this mechanism is excitonic in nature.

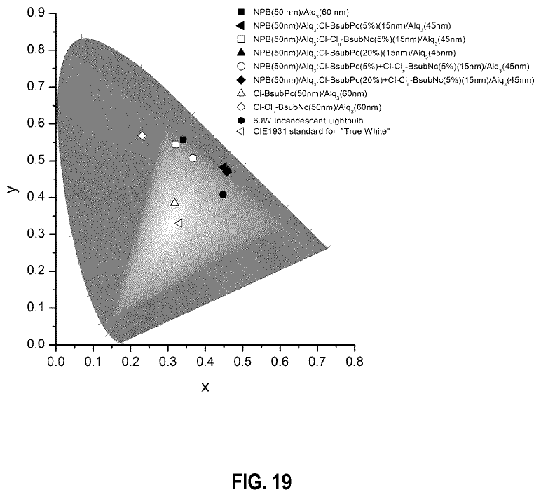

The CIE1931(x,y) co-ordinates for Example Devices B1-9 are plotted in FIG. 19. From these results, it was observed that Cl-BsubPc doped into Alq₃ produces white light which falls close to the CIE 1931 standard for a 60 W incandescent bulb of (0.44, 0.40). Increasing the concentration of Cl-BsubPc from 5% to 20% does not appreciably alter the color co-ordinates.

From the above Examples, it was observed that Cl-BsubPc and Cl-ClₙBsubNc can be used as dopant emitters in white emitting OLEDs, that the color of these OLEDs can be tuned as a function of dopant concentration and be incandescent-like. It was further observed that these two molecules can be co-doped to obtain combined orange-red emission, with the red contribution of Cl-ClₙBsubNc molecule being proportionally dependant on the emission contribution of the orange-emitting Cl-BsubPc. The net sum of these observations points to potential application of Cl-ClₙBsubNc in white emitting OLEDs aiming to simulate incandescent light sources.

The specific embodiments described above have been shown by way of example, and it should be understood that variations, modifications, or alternative forms may be made to the embodiments. It should be further understood that the claims are not intended to be limited to the particular forms disclosed, but rather to cover all modifications, equivalents, and alternatives falling within the spirit and scope of this disclosure. All references mentioned are hereby incorporated by reference in their entirety.

### REFERENCES

1. C. W. Tang, S. A. VanSlyke, Appl. Phys. Lett., 51 (1987), pp. 913-915.
2. T. Tsujimura, Y. Kobayashi, K. Murayama, A. Tanaka, M. Morooka, E. Fukumoto, H. Fujimoto, J. Sekine, K. Kanoh, K. Takeda, K. Miwa, M. Asano, N. Ikeda, S. Kohara, S. Ono, C.-T. Chung, R.-M. Chen, J.-W. Chung, C.-W. Huang, H.-R. Guo, C.-C. Yang, C.-C. Hsu, H.-J. Huang, W. Riess, H. Riel, S. Karg, T. Beierlein, D. Gundlach, S. Alvarado, C. Rost, P. Mueller, F. Libsch, M. Mastro, R. Polastre, A. Lien, J. Sanford, R. Kaufman, Dig. Tech. Pap.—Soc. Inf. Disp. Int. Symp., 34 (2003), pp. 6-9.
3. N. Thejo Kalyani, S. J. Dhoble, Renewable Sustainable Energy Rev., 16 (2012), pp. 2696-2723.
4. J. K. Jeong, J. H. Jeong, J. H. Choi, J. S. Im, S. H. Kim, H. W. Yang, K. N. Kang, K. S. Kim, T. K. Ahn, H.-J. Chung, M. Kim, B. S. Gu, J.-S. Park, Y.-G. Mo, H. D. Kim, H. K. Chung, Dig. Tech. Pap.—Soc. Inf. Disp. Int. Symp., 39 (2008), pp. 1-4.
5. C. Ego, D. Marsitzky, S. Becker, J. Zhang, A. C. Grimsdale, K. Mullen, J. D. MacKenzie, C. Silva, R. H. Friend, J. Am. Chem. Soc., 125 (2003), pp. 437-443.
6. V. A. Montes, G. Li, R. Pohl, J. Shinar, P. Anzenbacher, Adv. Mater., 16 (2004), pp. 2001-2003.
7. T. Shiga, H. Fujikawa, Y. Taga, J. Appl. Phys., 93 (2003), pp. 19-22.
8. A. A. Shoustikov, Y. You, M. E. Thompson, IEEE J. Sel. Top. Quantum Electron., 4 (1998), pp. 3-13.
9. C. F. Huebner, S. H. Foulger, Langmuir, 26 (2009), pp. 2945-2950.
10. Y. Sun, N.C. Giebink, H. Kanno, B. Ma, M. E. Thompson, S. R. Forrest, Nature, 440 (2006), pp. 908-912.
11. G. Schwartz, S. Reineke, T. C. Rosenow, K. Walzer, K. Leo, Adv. Funct. Mater., 19 (2009), pp. 1319-1333.
12. T. Komoda, N. Ide, J. Kido, J. Light Visual Environ., 32 (2008), pp. 75-78.
13. B. W. D'Andrade, S. R. Forrest, Adv. Mater., 16 (2004), pp. 1585-1595.
14. Z. Shen, P. E. Burrows, V. Bulović, S. R. Forrest, M. E. Thompson, Science, 276 (1997), pp. 2009-2011.
15. B. W. D'Andrade, S. R. Forrest, Adv. Mater., 16 (2004), pp. 1585-1595.
16. D. B. Boivin, J. F. Duffy, R. E. Kronauer, C. A. Czeisler, Nature, 379 (1996), pp. 540-542.
17. J. Hye Oh, S. Ji Yang, Y. Rag Do, Light: Sci. Appl., 3 (2014), p. e141.
18. L. Bellia, F. Bisegna, G. Spada, Building and Environment, 46 (2011), pp. 1984-1992.
19. S. M. Pauley, Med. Hypotheses, 63 (2004), pp. 588-596.
20. K. C. H. J. Smolders, Y. A. W. de Kort, P. J. M. Cluitmans, Physiol. Behav., 107 (2012), pp. 7-16.
21. G. Wyszecki, W. S. Stiles, Color science, Wiley New York, 1982.
22. Y. Ohno, Color rendering and luminous efficacy of white LED spectra, Optical Science and Technology, the SPIE 49th Annual Meeting, International Society for Optics and Photonics 2004, pp. 88-98.
23. P. Bodrogi, P. Csuti, P. Hotváth, J. Schanda, Why does the CIE colour rendering index fail for white RGB LED light sources?, CIE Expert Symposium on LED Light Sources: Physical Measurement and Visual and Photobiological Assessment 2004.
24. C. G. Claessens, D. González-Rodríguez, M. S. Rodríguez-Morgade, A. Medina, T. Torres, Chem. Rev., 114 (2014), pp. 2192-2277.
25. C. G. Claessens, D. González-Rodríguez, T. Torres, Chem. Rev., 102 (2002), pp. 835-854.
26. G. E. Morse, T. P. Bender, ACS Appl. Mater. Interfaces, 4 (2012), pp. 5055-5068.
27. M. G. Helander, G. E. Morse, J. Qiu, J. S. Castrucci, T. P. Bender, Z.-H. Lu, ACS Appl.

Mater. Interfaces, 2 (2010), pp. 3147-3152.
28. G. E. Morse, M. G. Helander, J. F. Maka, Z.-H. Lu, T. P. Bender, ACS Appl. Mater.

Interfaces, 2 (2010), pp. 1934-1944.
29. B. Verreet, S. Schols, D. Cheyns, B. P. Rand, H. Gommans, T. Aernouts, P. Heremans, J. Genoe, J. Mater. Chem., 19 (2009), pp. 5295-5297.
30. P. Heremans, D. Cheyns, B. P. Rand, Acc. Chem. Res., 42 (2009), pp. 1740-1747.
31. T. Sakai, H. Seo, T. Takagi, H. Ohtake, MRS Adv., 1 (2016), pp. 459-464.
32. K. Cnops, B. P. Rand, D. Cheyns, B. Verreet, M. A. Empl, P. Heremans, Nat. Commun., 5 (2014).
33. J. D. Dang, D. S. Josey, A. J. Lough, Y. Li, A. Sifate, Z.-H. Lu, T. P. Bender, J. Mater. Chem. A, (2016), 4, 24, 9566-9577.
34. G. E. Morse, A. S. Paton, A. Lough, T. P. Bender, Dalton Trans., 39 (2010), pp. 3915-3922.
35. K. L. Mutolo, E. I. Mayo, B. P. Rand, S. R. Forrest, M. E. Thompson, J. Am. Chem. Soc., 128 (2006), pp. 8108-8109.
36. N. Kobayashi, T. Ishizaki, K. Ishii, H. Konami, J. Am. Chem. Soc., 121 (1999), pp. 9096-9110.
37. N. Rubio, A. Jiménez-Banzo, T. Torres, S. Nonell, J. Photochem. Photobiol., A, 185 (2007), pp. 214-219.
38. Y. Tao, E. Balasubramaniam, A. Danel, P. Tomasik, Appl. Phys. Lett., 77 (2000), pp. 933-935.
39. D. Tanaka, T. Takeda, T. Chiba, S. Watanabe, J. Kido, Chem. Lett., 36 (2007), pp. 262-263.
40. Y. H. Kim, S. Y. Lee, W. Song, M. Meng, Z. H. Lu, W. Y. Kim, Synth. Met., 161 (2011), pp. 2211-2214.
41. S. Han, C. Huang, Z.-H. Lu, J. Appl. Phys., 97 (2005), p. 093102.
42. Z. Sun, B. Ding, B. Wu, Y. You, X. Ding, X. Hou, J. Phys. Chem. C, 116 (2012), pp. 2543-2547.
43. D. Pascale, A Review of RGB Color Spaces . . . from xyz to R′G′B′ TheBabelColor Company, 5700 Hector Desloges Montreal, Quebec, Canada, H1T 3Z6, 2003.
44. D. M. Berson, F. A. Dunn and M. Takao, Science, 2002, 295, 1070-1073.
45. J. A. Veitch and G. R. Newsham, Journal of the Illuminating Engineering Society, 1998, 27, 107-129.
46. B. del Rey, U. Keller, T. Torres, G. Rojo, F. Agulló-López, S. Nonell, C. Marti, S. Brasselet, I. Ledoux and J. Zyss, Journal of the American Chemical Society, 1998, 120, 12808-12817.
47. N. Kobayashi, Journal of Porphyrins and Phthalocyanines, 1999, 3, 453-467.
48. N. Beaumont, S. W. Cho, P. Sullivan, D. Newby, K. E. Smith and T. S. Jones, Advanced Functional Materials, 2012, 22, 561-566.
49. G. E. Morse, J. L. Gantz, K. X. Steirer, N. R. Armstrong and T. P. Bender, ACS Applied Materials & Interfaces, 2014, 6, 1515-1524.
50. J. S. Castrucci, D. S. Josey, E. Thibau, Z.-H. Lu and T. P. Bender, The journal of physical chemistry letters, 2015, 6, 3121-3125.
51. H. Gommans, S. Schols, A. Kadashchuk, P. Heremans and S. C. J. Meskers, The Journal of Physical Chemistry C, 2009, 113, 2974-2979.
52. K. T. Kamtekar, A. P. Monkman and M. R. Bryce, Advanced Materials, 2010, 22, 572-582.
53. G. M. Farinola and R. Ragni, Chemical Society Reviews, 2011, 40, 3467-3482.
54. P.-I. Shih, C.-F. Shu, Y.-L. Tung and Y. Chi, Applied Physics Letters, 2006, 88, 251110.
55. Y.-S. Huang, J.-H. Jou, W.-K. Weng and J.-M. Liu, Applied Physics Letters, 2002, 80, 2782-2784.
56. D. A. Poulsen, B. J. Kim, B. Ma, C. S. Zonte and J. M. J. Fréchet, Advanced Materials, 2010, 22, 77-82.
57. K. L. Paik, N. S. Baek, H. K. Kim, J.-H. Lee and Y. Lee, Macromolecules, 2002, 35, 6782-6791.
58. Y. Liu, M. Pan, Q.-Y. Yang, L. Fu, K. Li, S.-C. Wei and C.-Y. Su, Chemistry of Materials, 2012, 24, 1954-1960.
59. Y.-A. Li, S.-K. Ren, Q.-K. Liu, J.-P. Ma, X. Chen, H. Zhu and Y.-B. Dong, Inorganic Chemistry, 2012, 51, 9629-9635.
60. C.-T. Chen, Chemistry of Materials, 2004, 16, 4389-4400.
61. H. Gommans, T. Aernouts, B. Verreet, P. Heremans, A. Medina, C. G. Claessens and T. Torres, Advanced Functional Materials, 2009, 19, 3435-3439.
62. P. Sullivan, A. Duraud, I. Hancox, N. Beaumont, G. Mirri, J. H. R. Tucker, R. A. Hatton, M. Shipman and T. S. Jones, Advanced Energy Materials, 2011, 1, 352-355.
63. B. Verreet, B. P. Rand, D. Cheyns, A. Hadipour, T. Aernouts, P. Heremans, A. Medina, C. G. Claessens and T. Torres, Advanced Energy Materials, 2011, 1, 565-568.
64. D. S. Josey, J. S. Castrucci, J. D. Dang, B. H. Lessard and T. P. Bender, ChemPhysChem, 2015.
65. W. Z. Yuan, Y. Gong, S. Chen, X. Y. Shen, J. W. Y. Lam, P. Lu, Y. Lu, Z. Wang, R. Hu,
66. N. Xie, H. S. Kwok, Y. Zhang, J. Z. Sun and B. Z. Tang, Chemistry of Materials, 2012, 24, 1518-1528.
67. T. Plint, B. H. Lessard and T. P. Bender, Journal of Applied Physics, 2016, 119, 145502.

1. A light emitting composition comprising a light emitting agent comprising at least one boron subphthalocyanine (BsubPc) derivative as set out by formula: 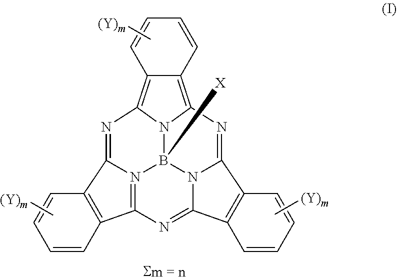
wherein X is a halogen, an alkoxy or a phenoxy,
wherein Y of each lobe is, independently, a hydrogen, a halogen, an alkoxy or a phenoxy,
wherein m is an integer that is 0, 1, 2, 3, or 4,
wherein n is an integer that is 0, 3, 6, 9, or 12;
and at least one boron subphthalocyanine with an extended π-conjugation (BsubNc) derivative as set out by formula: 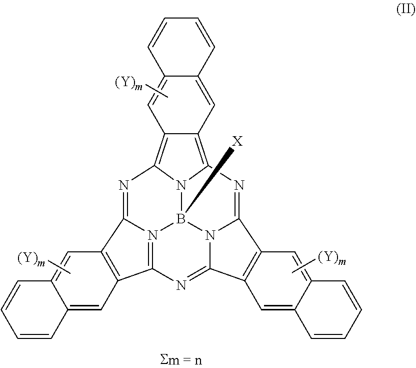
wherein X is a halogen, an alkoxy or a phenoxy,
wherein Y of each lobe is, independently, a hydrogen, a halogen, an alkoxy or a phenoxy,
wherein m is an integer chosen from 0, 1 or 2,
wherein n is an integer chosen from 3 or 6; or
any combination thereof.

2. The light emitting composition of claim 1, wherein the X is fluorine, chlorine, bromine or iodine.

3. The light emitting composition of claim 2, wherein the X is fluorine or chlorine.

4. The light emitting composition of claim 1, wherein the Y is fluorine, chlorine, bromine or iodine.

5. The light emitting composition of claim 2, wherein the Y is fluorine or chlorine.

6. The light emitting composition of claim 1, wherein the at least one BsubPc derivative comprises Cl-BsubPc, Cl-ClₙBsubNc, Cl—Cl₆-BsubPc or any combination thereof.

7. The light emitting composition of claim 1, wherein the at least one BsubPc derivative comprises Cl-BsubPc and Cl-ClₙBsubNc.

8. The light emitting composition of claim 7, wherein the Cl-ClₙBsubNc is configured to absorb at least a portion of the photons emitted by the Cl-BsubPc.

9. The light emitting composition of claim 1, wherein the at least one boron subphthalocyanine derivative exhibits a primary electroluminescent peak and wherein the at least one boron subphthalocyanine derivative is configured to exhibit a secondary electroluminescent peak.

10. The light emitting composition of claim 1, further comprising a host material.

11. The light emitting composition of claim 10, wherein the host material comprises Alq₃ or NPB.

12. The light emitting composition of claim 10, wherein the host material comprises Alq₃.

13. The light emitting composition of claim 1, wherein the light emitting composition consists of the at least one boron subphthalocyanine derivative.

14. An organic light emitting diode (OLED) comprising an emissive material comprising at least one boron subphthalocyanine (BsubPc) derivative as set out by formula: 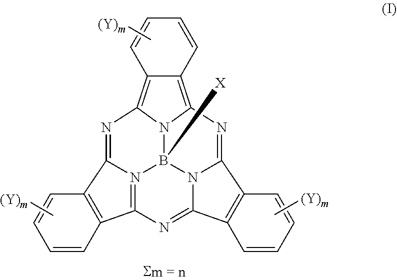
wherein X is a halogen, an alkoxy or a phenoxy,
wherein Y of each lobe is, independently, a hydrogen, a halogen, an alkoxy or a phenoxy,
wherein m is an integer that is 0, 1, 2, 3, or 4,
wherein n is an integer that is 0, 3, 6, 9, or 12;
and at least one boron subphthalocyanine with an extended π-conjugation (BsubNc) derivative as set out by formula: 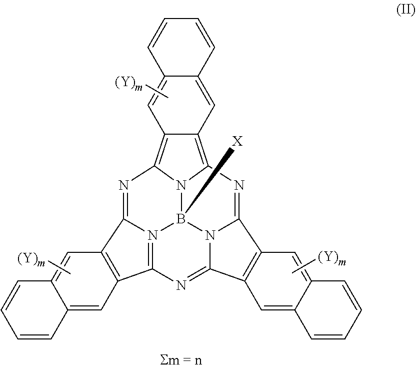
wherein X is a halogen, an alkoxy or a phenoxy,
wherein Y of each lobe is, independently, a hydrogen, a halogen, an alkoxy or a phenoxy,
wherein m is an integer that is 0, 1 or 2,
wherein n is an integer that is 3 or 6; or
any combination thereof.

15. The OLED of claim 14, further comprising:
an electron transport layer (ETL); and
a hole transport layer (HTL).

16. The OLED of claim 15, wherein the ETL comprises Alq₃.

17. The OLED of claim 15, wherein the HTL comprises NPB.

18. The OLED of claim 15, wherein the ETL has a thickness of between about 30 nm and about 60 nm.

19. The OLED of claim 15, wherein the HTL has a thickness of between about 35 nm and about 50 nm.

20. The OLED of claim 15, further comprising an interlayer, the interlayer comprises the emissive material.

21. The OLED of claim 20, wherein the interlayer has a thickness of between about 1 nm and about 60 nm.

22. The OLED of claim 15, wherein the hole transport layer comprises the emissive material.

23. The OLED of claim 14, wherein the OLED produces light having at least one of a CRI of at least 60; an R9 value of at least about 0; and/or a CIE 1931 coordinate similar to that of a 60 W incandescent bulb of (0.44, 0.40).

24. (canceled)

25. (canceled)

26. A light emitting composition comprising a light emitting agent comprising at least one boron subphthalocyanine derivative as set out by formula: 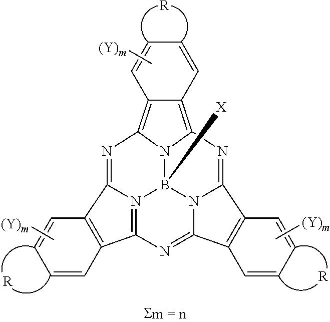
wherein R is present or absent and wherein, when present, R is a fused benzene ring;
wherein X is a halogen, an alkoxy or a phenoxy,
wherein Y of each lobe is, independently, a hydrogen, a halogen, an alkoxy or a phenoxy,
wherein m is an integer that is 0, 1 or 2,
wherein n is an integer that is 3 or 6; or
any combination thereof.
